(19) United States
(12) Patent Application Publication
(10) Pub. No.: US 2025/0132684 A1
(43) Pub. Date: Apr. 24, 2025

(54) SIGNAL TRANSMISSION CIRCUIT AND POWER CONVERSION APPARATUS

(71) Applicant: Mitsubishi Electric Corporation, Tokyo (JP)

(72) Inventors: Yuto SHIBUTA, Fukuoka (JP); Shohei HIGASHI, Fukuoka (JP)

(73) Assignee: Mitsubishi Electric Corporation, Tokyo (JP)

(21) Appl. No.: 18/764,518

(22) Filed: Jul. 5, 2024

(30) Foreign Application Priority Data
Oct. 19, 2023 (JP) 2023-180219

(51) Int. Cl. H02M 3/335; H02M 1/00; H02M 1/088

(52) U.S. Cl. CPC H02M 3/33515; H02M 1/0022; H02M 1/088; H02M 3/33592

(57) ABSTRACT

A first circuit generates a transmission signal according to a change in a logical value of a first signal using a first potential as a reference. A transformer includes a first coil to which a transmission signal is input and a second coil inductively coupled to the first coil to output a pair of reception signals. The second circuit generates a second signal by performing comparison with hysteresis with respect to the potential difference between the pair of reception signals using a second potential as a reference. The second circuit includes a detection circuit performing comparison and outputting a result of detecting whether the potential difference exceeds a predetermined range as the second signal, and a reset circuit resetting an operation of the detection circuit when a logical value of the second signal is maintained in a preset period.

### BACKGROUND OF THE INVENTION

### Field of the Invention

The present disclosure relates to a signal transmission circuit and a power conversion apparatus.

### Description of the Background Art

The signal transmission circuit disclosed in WO 2018/066165 A includes a transformer including a first coil and a second coil, a first circuit connected to the first coil, and a second circuit connected to the second coil. A first signal is input to the first circuit. A second signal is output from the second circuit.

The second circuit includes a detection circuit, two rectifier circuits, a control circuit, and two output resistors. The detection circuit detects the voltage signal generated at each of both ends of the second coil and generates and outputs a second signal based on the voltage signal. The control circuit controls control voltages applied to the two rectifier circuits and controls bias voltages respectively sent to the rectifier circuits via the output resistors.

The power conversion apparatus disclosed in WO 2018/066165 A includes two signal transmission circuits, each described above, two switching elements, and two driver units. The second circuit of each signal transmission circuit is connected to an input terminal of a corresponding one of the driver units. An output terminal of each driver unit is connected to an input terminal of a corresponding one of the switching elements.

The voltage across the two ends of the second coil varies due to, for example, the opening and closing of the switching element. The suppression of the variation of the voltage at the two ends of the second coil contributes to the suppression of a malfunction of the detection circuit connected to the second coil, and eventually, the suppression of a malfunction of the opening and closing of the switching element.

In order to suppress the variation of the voltage at both ends of the second coil and eventually suppress the malfunction of the second circuit, the control voltage and the bias voltage provided to the two rectifier circuits are controlled. When the temporal change amount of potential due to the opening and closing of the switching element is significant, an event in which the opening and closing of the switching element cannot prevent the malfunction of the second circuit is assumed. It is desirable to suppress the occurrence of such an event from the viewpoint of suppressing the second signal from reflecting the first signal in the signal transmission circuit and eventually suppressing the malfunction of the opening and closing of the switching element in the power conversion apparatus.

### SUMMARY

An object of a signal transmission circuit according to the present disclosure is to appropriately transmit a signal. An object of a power conversion apparatus according to the present disclosure is to suppress the malfunction of the switching element.

A signal transmission circuit according to the present disclosure includes a first circuit, to which a first signal is input, configured to generate a transmission signal according to a change in a logical value of the first signal, and use a first potential as a reference for an operation, a transformer including a first coil to which the transmission signal is input from the first circuit and a second coil inductively coupled to the first coil and configured to output a pair of reception signals, and a second circuit, to which the pair of reception signals are input from the second coil, configured to generate a second signal by performing comparison with hysteresis with respect to a potential difference between the pair of reception signals, and use a second potential as a reference for an operation. The second circuit includes a detection circuit configured to perform the comparison and output a result of detecting whether the potential difference exceeds a predetermined range as the second signal, and a reset circuit configured to reset an operation of the detection circuit when a logical value of the second signal is maintained in a preset period.

According to the signal transmission circuit according to the present disclosure, a signal is appropriately transmitted.

A power conversion apparatus according to the present disclosure includes an output line, a first switching element having one end to which a fixed potential is applied and the other end connected to the output line, a second switching element having one end connected to the output line and the other end to which a third potential is applied and configured to be turned on exclusively with respect to the first switching element, a first signal transmission circuit as which any one of the first to fifth aspects of the signal transmission circuit according to the present disclosure is adopted, a second signal transmission circuit as which any one of the first to fifth aspects of the signal transmission circuit according to the present disclosure is adopted, and a first latch circuit configured to output a signal for controlling whether to permit conduction of the first switching element, be set by the second signal output from the first signal transmission circuit, and be reset by the second signal output from the second signal transmission circuit. Both the second potential in the first signal transmission circuit and the second potential in the second signal transmission circuit are the potential of the output line.

The power conversion apparatus according to the present disclosure can obtain the advantage of the signal transmission circuit signal according to the present disclosure.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a circuit diagram illustrating the configuration of a signal transmission circuit 1000 according to a first preferred embodiment;

FIG. 2 is a waveform diagram illustrating temporal changes in various signals according to the first preferred embodiment;

FIG. 3 is a waveform diagram for explaining the advantage of providing a self-reset circuit 241;

FIG. 4 is a circuit diagram illustrating the configuration of a power conversion apparatus 2000 according to a second preferred embodiment;

FIG. 5 is a circuit diagram illustrating the configuration of a signal transmission circuit 1000a;

FIG. 6 is a circuit diagram illustrating the configuration of a signal transmission circuit 1000b;

FIG. 7 is a circuit diagram illustrating the configuration of a signal transmission circuit 1000x;

FIG. 8 is a circuit diagram illustrating the configuration of a signal transmission circuit 1000y;

FIG. 9 is a waveform diagram illustrating temporal changes in various signals in the signal transmission circuits 1000a and 1000b;

FIG. 10 is a waveform diagram illustrating temporal changes in various signals in the signal transmission circuits 1000x and 1000y;

FIG. 11 is a graph illustrating the rectification characteristics of a diode;

FIG. 12 is a waveform diagram illustrating various signals in a third preferred embodiment;

FIG. 13 is a circuit diagram illustrating the configuration of a signal transmission circuit 1000 to which a first circuit 100 according to a fourth preferred embodiment is applied;

FIG. 14 is a circuit diagram showing a path through which a displacement current Idev2 flows;

FIG. 15 is a circuit diagram showing a path through which a displacement current Idev1 flows;

FIG. 16 is a waveform diagram illustrating temporal changes in various signals in the first circuit 100 according to the fourth preferred embodiment; and

FIG. 17 is a circuit diagram illustrating the configuration of a signal transmission circuit 1000 to which a first circuit 100 according to a fifth preferred embodiment is applied.

### DESCRIPTION OF THE PREFERRED EMBODIMENTS

### <1. Signal Transmission Circuit>

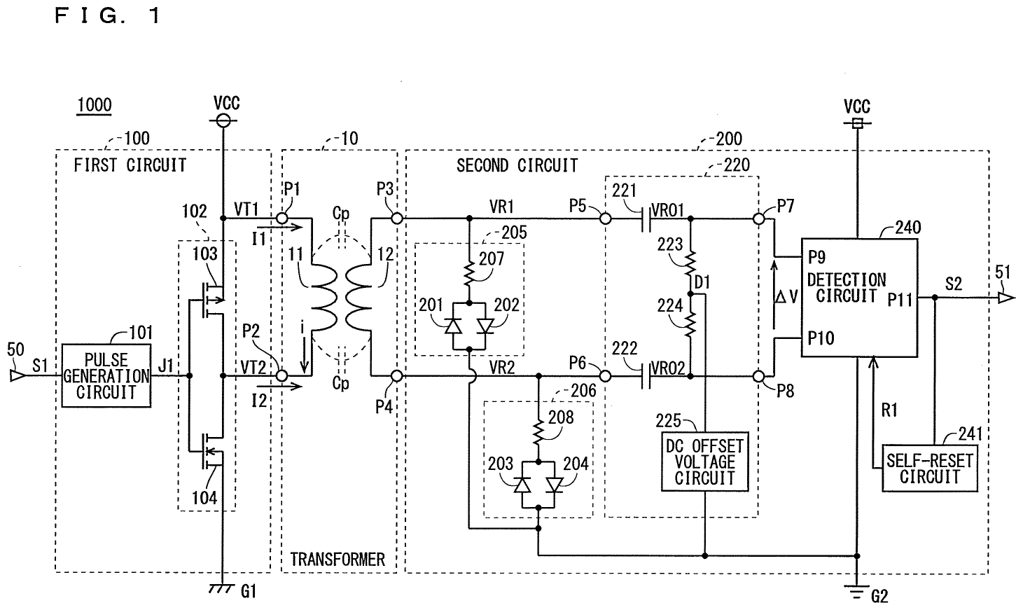

A first preferred embodiment of the present disclosure relates to a signal transmission circuit. FIG. 1 is a circuit diagram illustrating the configuration of a signal transmission circuit 1000 according to a first preferred embodiment.

The signal transmission circuit 1000 includes an input terminal 50, a first circuit 100, a transformer 10, a second circuit 200, and an output terminal 51. The input terminal 50 may be considered to be included in the first circuit 100. It may be considered that the output terminal 51 is included in the second circuit 200.

### <1-1. First Circuit 100>

The first circuit 100 includes a pulse generation circuit 101 and an output circuit 102. A first signal S1 is input to the first circuit 100 via the input terminal 50. The first signal S1 indicates two logical values. The first signal S1 ideally has a rectangular wave but may have a waveform with a gentle curve to the extent that the first signal S1 can be discriminated into two logical values by the pulse generation circuit 101.

### <1-2. Pulse Generation Circuit 101>

The pulse generation circuit 101 outputs a signal J1 corresponding to a change in the value of the first signal S1. Specifically, the pulse generation circuit 101 discriminates the value of the first signal S1 into two logical values of “H” and “L”. The pulse generation circuit 101 outputs a train of a plurality of pulses (to be simply referred to as a “pulse train” hereinafter) or a single pulse in the signal J1 in response to the transition of the first signal S1 from “L” to “H”. The following is a case where a pulse train occurs mainly in the signal J1.

The pulse generation circuit 101 stops outputting a pulse train in the signal J1 in response to the transition of the first signal S1 from “H” to “L”. The pulse generation circuit 101 is implemented by, for example, a multivibrator.

The so-called pulse width of a pulse in the signal J1, the length of a period during which the pulse takes “H”, has a specified value. The specified value is shorter than a period assumed as the interval between the adjacent transitions of the two logical values of the first signal S1 in opposite directions. The pulse train continues to be generated in response to the transition of the first signal S1 from “L” to “H”, and the generation of the pulse train is stopped in response to the transition of the first signal S1 from “H” to “L”.

### <1-3. Output Circuit 102>

The output circuit 102 receives the signal J1 and outputs a transmission signal VT2 reflecting the signal J1. Since the output circuit 102 is a component of the first circuit 100 together with the pulse generation circuit 101, it can be said that the transmission signal VT2 is a signal corresponding to the waveform of the first signal S1 generated by the first circuit 100 and input to the first circuit 100, specifically, a change in the logical value of the first signal S1.

For example, the output circuit 102 is implemented by an inverter having field effect transistors (to be also simply referred to as “transistors” hereinafter) 103 and 104. For example, a P-channel transistor is adopted as the transistor 103, and for example, an N-channel transistor is adopted as the transistor 104.

Transistor 103 has a gate, a source, and a drain. It can be said that the source and the drain are a first electrode and a second electrode that are electrically connected to each other via a signal applied to the gate. It can be said that the gate is a third electrode that controls conduction between the first electrode and the second electrode. Similarly, the transistor 104 has a source as a first electrode, a drain as a second electrode, and a gate as a third electrode.

The signal J1 is applied to both the gate of the transistor 103 and the gate of the transistor 104. The drain of the transistor 103 and the drain of the transistor 104 are connected to each other, and the potential of these drains is output as the transmission signal VT2 from the output circuit 102 and eventually from the first circuit 100. A potential G1 is a reference for the potential of these drains. Specifically, the potential G1 of the first circuit 100 is applied to the source of the transistor 104, and a fixed potential VCC higher than the potential G1 is applied to the source of the transistor 103. In this manner, the potential G1 is a reference for the operation of the first circuit 100. A potential VT1 of the source of the transistor 103 is output from the output circuit 102 and eventually from the first circuit 100.

The transformer 10 includes a first coil 11 and a second coil 12. The first coil 11 and the second coil 12 are inductively coupled. The transformer 10 has a first end P1, a second end P2, a third end P3, and a fourth end P4. One end of the first coil 11 is connected to the first end P1, and the other end is connected to the second end P2. One end of the second coil 12 is connected to the third end P3, and the other end is connected to the fourth end P4. Parasitic capacitances Cp exist between the first end P1 side of the first coil 11 and the third end P3 side of the second coil 12 and between the second end P2 side of the first coil 11 and the fourth end P4 side of the second coil 12.

The source of the transistor 103 is connected to the first end P1, to which the potential VT1 is input from the first circuit 100. The drain of the transistor 103 and the drain of the transistor 104 are connected to the second end P2, to which the transmission signal VT2 is input from the first circuit 100.

When a pulse rises in the signal J1, the transistor 103 transitions from the ON state to the OFF state, and the transistor 104 transitions from the OFF state to the ON state. The potential VT1 is output from the first circuit 100, and the potential G1 is output as the transmission signal VT2. A current from the first end P1 to the second end P2 flows through the first coil 11. Due to an increase in current when the current starts to flow, the potential of the third end P3 increases and the potential of the fourth end P4 decreases so as to prevent the increase.

When a pulse falls in the signal J1, the transistor 103 transitions from the OFF state to the ON state, and the transistor 104 transitions from the ON state to the OFF state. Both ends of the first coil 11 are short-circuited via the transistor 103 in the first circuit 100, and a current flowing through the first coil 11 decreases. Due to the reduction, the potential of the third end P3 decreases and the potential of the fourth end P4 increases so as to prevent the reduction.

The potential of the third end P3 is input to the second circuit 200 as a reception signal VR1. The potential of the fourth end P4 is input to the second circuit 200 as a reception signal VR2. The second coil 12 outputs the pair of reception signals VR1 and VR2. A reference for the potentials of the reception signals VR1 and VR2 is a potential G2 serving as a reference for the operation of the second circuit 200. The potential difference between the potentials G1 and G2 may vary.

### <1-4. Second Circuit 200>

The second circuit 200 includes a detection circuit 240, an offset circuit 220, and clamp circuits 205 and 206. A potential serving as a reference for the operation of the second circuit 200 is the potential G2.

The offset circuit 220 has input terminals P5 and P6 and output terminals P7 and P8. The reception signal VR1 is provided to the input terminal P5, and the reception signal VR2 is provided to the input terminal P6. A signal VRO1 is output from the output terminal P7, and a signal VRO2 is output from the output terminal P8. The offset circuit 220 applies offset voltages to the reception signals VR1 and VR2 to generate the signals VRO1 and VRO2, respectively.

### <1-5. Detection Circuit 240>

The detection circuit 240 has input ends P9 and P10 and an output end P11. The signal VRO1 is provided to the input end P9, and the signal VRO2 is provided to the input end P10. A second signal S2 is output from the output end P11. The second signal S2 is output from the output terminal 51. The detection circuit 240 operates with the potential G2 serving as a reference.

The second signal S2 takes potentials corresponding to two logical values “H” and “L” depending on the potential difference between the signals VRO1 and VRO2, specifically, a value AV obtained by subtracting the potential of the signal VRO2 from the potential of the signal VRO1 (to be tentatively referred to as a “subtraction voltage value” hereinafter). Specifically, the detection circuit 240 is configured to (i) raise the logical value of the second signal S2 from “L” to “H” in response to a change from a state where the subtraction voltage value ΔV is less than a positive first threshold value to a state where the subtraction voltage ΔV is equal to or more than the first threshold value, (ii) lower the logical value of the second signal S2 from “H” to “L” in response to a change from a state where the subtraction voltage value ΔV is more than a negative second threshold value to a state where the subtraction voltage ΔV is equal to or less than the second threshold value, (iii) maintain the state of the logical value of the second signal S2 even when there is a variation in the subtraction voltage value ΔV other than those in (i) and (ii) described above, and (iv) set the logical value of the second signal S2 to “L” by resetting in preference to the operations in (i) to (iii) described above.

In view of such an operation, the signals VRO1 and VRO2 can also be considered as a pair of detection signals. The detection circuit 240 performs comparison with hysteresis between the pair of reception signals VR1 and VR2 using the first threshold and the second threshold, detects whether the potential difference between the reception signals VR1 and VR2 exceeds a predetermined range, and generates the detection result as the second signal S2.

For example, the detection circuit 240 is implemented by a hysteresis comparator or a Schmitt trigger circuit. The potentials G2 and VCC are applied to the detection circuit 240, and the potential difference between them is the operating voltage of the detection circuit 240. The potential VCC applied to the detection circuit 240 is higher than the potential G2. The potential VCC applied to the detection circuit 240 and the potential VCC applied to the output circuit 102 may be different.

### <1-6. Offset Circuit 220>

The offset circuit 220 includes voltage dividing resistors 223 and 224 and capacitors 221 and 222. The voltage dividing resistor 223 and the capacitor 221 implement an RC high-pass filter and bring about the effect of removing noise of a low-frequency component and a DC component of the reception signal VR1. The voltage dividing resistor 224 and the capacitor 222 implement an RC high-pass filter and bring about the effect of removing noise of a low-frequency component and a DC component of the reception signal VR2.

Specifically, the capacitor 221 is connected between the input terminal P5 and the output terminal P7, and the capacitor 222 is connected between the input terminal P6 and the output terminal P8. One end of the voltage dividing resistor 223 is connected to the output terminal P7. One end of the voltage dividing resistor 224 is connected to the output terminal P8. The other end of the voltage dividing resistor 223 and the other end of the voltage dividing resistor 224 are, for example, connected, and a DC voltage D1 with reference to the potential G2 is applied as an offset voltage (which can also be regarded as a bias voltage) to both the ends.

Since the DC voltage D1 is applied as an offset voltage to both the reception signals VR1 and VR2 to generate the signals VRO1 and VRO2, the subtraction voltage value ΔV can be considered as the potential difference between the reception signals VR1 and VR2, specifically, the value obtained by subtracting the potential of the reception signal VR2 from the potential of the reception signal VR1. From this viewpoint, it can be considered that the second circuit 200 performs comparison with hysteresis with respect to the potential difference between the pair of reception signals VR1 and VR2 and generates the second signal S2 as a result of the comparison.

Performing the comparison by the detection circuit 240 on the basis of the pair of signals VRO1 and VRO2 contributes to reducing the influence of variation in the potential G2 and eventually the influence of a voltage variation Vdif (to be described later) as compared with the case of performing the comparison on the basis of the pair of reception signals VR1 and VR2.

For example, the offset circuit 220 includes a DC offset voltage circuit 225. The DC offset voltage circuit 225 outputs the DC voltage D1 with reference to the potential G2. The DC offset voltage circuit 225 is implemented by, for example, a known DC voltage source. The DC offset voltage circuit 225 may be provided outside the offset circuit 220.

For example, the DC voltage D1 is set to, for example, a median value in a voltage range (to be temporarily referred to as an “appropriate voltage range” hereinafter) at the input ends P9 and P10 in which the detection circuit 240 can appropriately perform the above operation. Alternatively, the DC voltage D1 may be set according to the characteristics of the reception signals VR1 and VR2 or the performance of the detection circuit 240.

Assume that the appropriate voltage range is 0 V to 5 V with reference to the potential G2, the maximum value of the reception signal VR1 is 1 V, and the minimum value of the reception signal VR2 is −1 V. In this case, 2.5 V is adopted as the DC voltage D1. Adopting this voltage will make the maximum value of the signal VRO1 become 3.5 V and can obtain a margin of 1.5 (=5-3.5) V at the upper limit of the appropriate voltage range. Adopting the above voltage will make the minimum value of the signal VRO2 become 1.5 V and can obtain a margin of 1.5 (=1.5-0) V at the lower limit of the appropriate voltage range.

Assume that the appropriate voltage range is 0 V to 5 V with reference to the potential G2, the maximum value of the reception signal VR1 is 1.2 V, and the minimum value of the reception signal VR2 is −0.8 V. In this case, 2.3 V is adopted as the DC voltage D1. By adopting this voltage, a margin of 1.5 V is obtained at both the upper limit and the lower limit of the appropriate voltage range.

Assume that the appropriate voltage range is 1 V to 5 V with reference to the potential G2, the maximum value of the reception signal VR1 is 1 V, and the minimum value of the reception signal VR2 is −1 V. In this case, 3 V is adopted as the DC voltage D1. By adopting this voltage, a margin of 1 V is obtained at both the upper limit and the lower limit of the appropriate voltage range.

The voltage dividing resistors 223 and 224 and the transformer 10, more specifically, the voltage dividing resistors 223 and 224 and the second coil 12 are connected via the capacitors 221 and 222. Owing to the presence of the capacitors 221 and 222, variation in the reception signals VR1 and VR2 is less likely to be reduced even when the impedances of the voltage dividing resistors 223 and 224 are small, and variation in the DC voltage D1 is suppressed even when the impedances of the voltage dividing resistors 223 and 224 are large. Therefore, there is a design advantage that the design of the voltage dividing resistors 223 and 224 is facilitated.

The input impedance of the second circuit 200 can be adjusted by setting the offset circuit 220, specifically, by setting the respective impedances of the voltage dividing resistors 223 and 224 and the capacitors 221 and 222. Such adjustment contributes to increasing the potential difference between the reception signals VR1 and VR2.

For example, the potential difference between the reception signals VR1 and VR2 can be adjusted by adjusting the values of the capacitors 221 and 222 to perform impedance matching between the second circuit 200 and the transformer 10. Impedance matching contributes to an improvement in SN ratio. Also in this case, it is possible to suppress the variation in the DC voltage D1 and to obtain a design advantage.

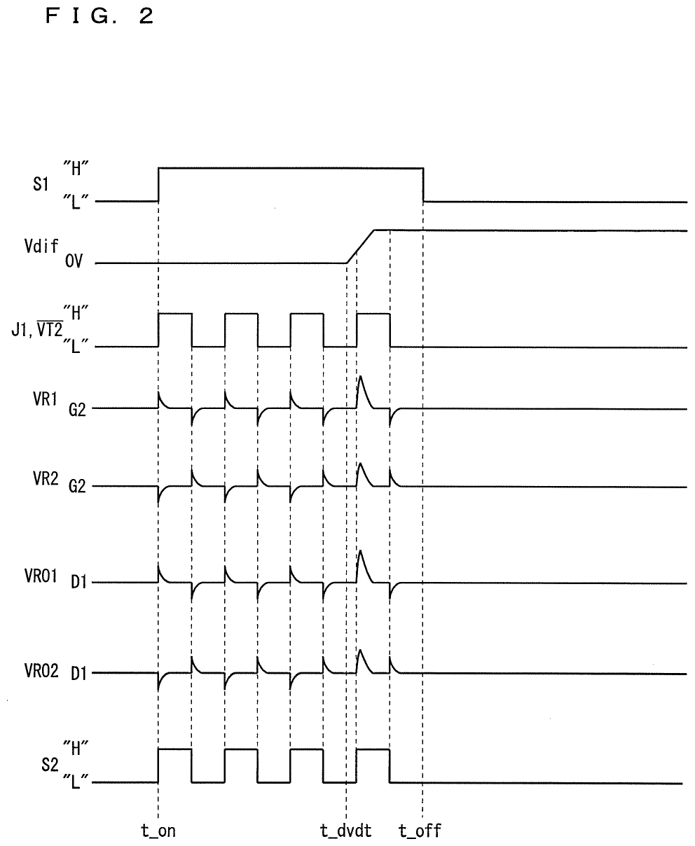

FIG. 2 is a waveform diagram illustrating temporal changes in various signals. Specifically, FIG. 2 illustrates the respective waveforms of the logical value of the first signal S1, the logical value of the signal J1, the reception signals VR1 and VR2, the signals VRO1 and VRO2, and the logical value of the second signal S2. FIG. 2 also illustrates the waveform of the voltage variation Vdif to be described later.

The logical value of the first signal S1 transitions (rises) from “L” to “H” at time t_on. The logical value of the first signal S1 transitions (falls) from “H” to “L” at time t_off.

The signal J1 outputs a pulse train in a period in which the logical value of the first signal S1 is at “H”. FIG. 2 illustrates a case where the signal J1 outputs four pulses in a period in which the logical value of the first signal S1 is at “H”. Owing to the function of the output circuit 102, the logical value of the transmission signal VT2 is an inversion of the logical value of the signal J1, and the logical value of the signal J1 is an inversion of the logical value of the transmission signal VT2. FIG. 2 illustrates an inversion of the logical value of the transmission signal VT2 together with the signal J1 by adding an overbar above the symbol “VT2”.

Both the reception signals VR1 and VR2 vary with reference to the potential G2. At the time when a pulse in the signal J1 rises, a current from the first end P1 toward the second end P2 starts to flow in the first coil 11. FIG. 2 illustrates the waveforms in which the reception signals VR1 and VR2 temporarily rise and fall, respectively, at this time and attenuate thereafter. At this time, a current i flowing through the first coil 11 and a mutual inductance L between the first coil 11 and the second coil 12 are introduced. The value of the reception signal VR1 is represented by L·(di/dt), and the value of the reception signal VR2 is represented by −L·(di/dt).

FIG. 2 illustrates the waveforms in which the reception signals VR1 and VR2 temporarily fall and rise, respectively, at the time when a pulse in the signal J1 falls and attenuate thereafter. The value of the reception signal VR1 at this time is represented by −L·(di/dt), and the value of the reception signal VR2 is represented by L·(di/dt).

As described above, since the value of the time derivative (di/dt) of the current i determines the reception signals VR1 and VR2, the current i functions similarly to the transmission signal VT2 in terms of responding to a change in the logical value of the first signal S1. It can be said that the first circuit 100 generates the current i according to a change in the logical value of the first signal S1 and the current i is input to the first coil 11. For example, it can also be said that the transmission signal VT2 is output as the potential of the drain of the transistor 104 from the drain, and the current i is a transmission signal output from the drain of the transistor 104 as a current flowing through the drain.

FIG. 2 illustrates the waveform in which the reception signal VR2 rises at the time when a pulse in the signal J1 rises in a period in which the voltage variation Vdif rises (hereinafter, a “rise period”) and attenuates thereafter. The voltage variation Vdif indicates the voltage of the potential G1 with reference to the potential G2. Specifically, when a voltage variation amount per unit time (to be also simply referred to as a “time derivative”) dv/dt is generated in the potential G2 with reference to the potential G1, the voltage determined by the product of a certain time constant and the time derivative dv/dt corresponds to the voltage variation Vdif. The time constant is the product of the electrostatic capacitance value of the parasitic capacitance Cp and the resistance value of an equivalent resistance R\hat{ } of the second circuit 200. The equivalent resistance R\hat{ } includes the resistance components of the clamp circuits 205 and 206 and the wiring resistance of the second circuit 200.

The voltage variation Vdif with reference to the potential G2 and is in the relationship of Vdif=−(dv/dt)·Cp·R\hat{ } (where the symbol Cp represents the capacitance value of the parasitic capacitance Cp, and the symbol R\hat{ } represents the resistance value of the equivalent resistance R\hat{ }) in a rise period.

When the speed at which the potential G2 decreases from the potential G1 increases, the voltage variation Vdif increases. At this time, the parasitic capacitance Cp is charged by a displacement current due to the voltage variation Vdif. FIG. 2 illustrates a state in which the voltage variation Vdif starts to rise at time t_dvdt, and the rise of the fourth pulse in the signal J1 occurs during a rise period. When a pulse rises in the signal J1 during a rise period, the amount by which the reception signal VR1 rises from the potential G2 increases, reflecting a decrease in the potential G2. The reception signal VR2 does not fall from the potential G2 and rises from the potential G2 by an amount smaller than the amount by which the reception signal VR1 rises. Alternatively, the reception signal VR2 falls from the potential G2 by a small amount as compared with a state in which the voltage variation Vdif has not increased. After a pulse rises in the signal J1, a current from the first end P1 to the second end P2 decreases, and the reception signals VR1 and VR2 attenuate and return to the potential G2.

When the time derivative dv/dt of the voltage does not occur at the potential G2, the voltage variation Vdif becomes a steady state. Therefore, at a trailing edge of the fourth pulse in the signal J1 after the voltage variation Vdif becomes the steady state, the reception signals VR1 and VR2 behave similarly to the case of the falling of the other pulses.

FIG. 2 illustrates a case where the subtraction voltage value ΔV has changed from a state of being less than the first threshold value to the first threshold value or more even during a rise period and illustrates a case where the logical value of the second signal S2 rises from “L” to “H” according to the operation (i).

The case where a pulse falls in the signal J1 during a rise period will be described later in “<1-7. Self-reset Circuit 241>”.

The signals VRO1 and VRO2 have waveforms similar to the waveforms of the reception signals VR1 and VR2, respectively. Owing to the high-pass filter obtained by the capacitor 221 and the voltage dividing resistor 223 and the DC offset voltage circuit 225, the signal VRO1 exhibits a leading edge, a subsequent decay, a trailing edge, and a subsequent decay similar to the reception signal VR1 with reference to the DC voltage D1. Owing to the high-pass filter obtained by the capacitor 222 and the voltage dividing resistor 224 and the DC offset voltage circuit 225, the signal VRO2 exhibits a leading edge and a subsequent decay similar to the reception signal VR2 with reference to the DC voltage D1.

Since the detection circuit 240 operates as described above, a pulse train appears in the second signal S2 in correspondence with a pulse train generated in the signal J1 based on the first signal S1. The interval between adjacent transitions in the pulse train appearing in the signal J1 is equal to the interval between adjacent transitions in the pulse train appearing in the second signal S2 in correspondence with the pulse train.

### <1-7. Self-reset Circuit 241>

The second circuit 200 includes a self-reset circuit 241. The second signal S2 is input to the self-reset circuit 241, and the self-reset circuit 241 outputs a reset signal R1. The reset signal R1 is input to the detection circuit 240 and causes the detection circuit 240 to reset its operation.

The self-reset circuit 241 prevents the second signal S2 from becoming “H” beyond a preset period (to be also temporarily referred to as an “allowable period” hereinafter). Specifically, the self-reset circuit 241 activates the reset signal R1 when the allowable period elapses after the logic value of the second signal S2 rises. The detection circuit 240 is reset by the activation of the reset signal R1. This resetting operation sets the logical value of the second signal S2 to “L” (see (iv) described above). The self-reset circuit 241 functions as a reset circuit that resets the operation of the detection circuit 240 in the signal transmission circuit 1000 itself when the logic value of the second signal S2, “H” in this case, is maintained in the allowable period.

The self-reset circuit 241 is implemented by, for example, a timer that starts at a leading edge of the logical value of the second signal S2 and outputs the one-pulse reset signal R1 in response to the elapse of the allowable period.

For example, the self-reset circuit 241 includes a capacitor that is charged with a constant current while a logic value of the second signal S2 is “H”, and is configured to output a reset signal R1 of one pulse when a voltage charged in the capacitor exceeds a threshold value.

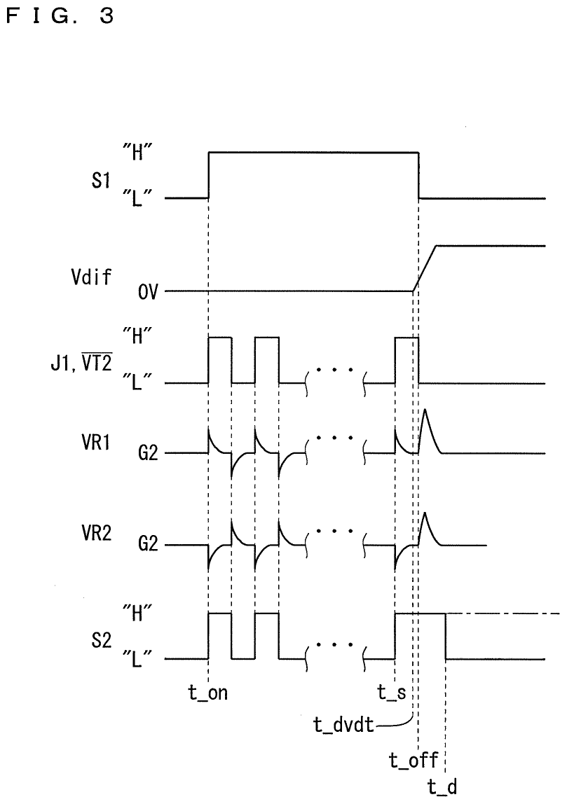

FIG. 3 is a waveform diagram for explaining the advantage of providing the self-reset circuit 241. FIG. 3 illustrates the respective waveforms of the logical value of the first signal S1, the logical value of the signal J1, the reception signals VR1 and VR2, and the logical value of the second signal S2. FIG. 3 also illustrates an inversion of the logical value of the transmission signal VT2 together with the signal J1 by adding an overbar above the symbol “VT2”. Referring to FIG. 3, the logical value of the first signal S1 rises at time t_on and falls at time t_off.

The last pulse of the pulse train appearing in the signal J1 rises at time t_s. FIG. 3 illustrates a case where the last pulse of the pulse train appearing in the signal J1 also falls at time t_off but sometimes falls before time t_off.

FIG. 3 illustrates a case where the voltage variation Vdif is 0 V from time t_on to time t_dvdt (that is, the potential G1 is equal to the potential G2) and starts to rise from time t_dvdt.

Referring to FIG. 3, the symbol “ . . . ” in each of the logical value of the signal J1, the reception signals VR1 and VR2, and the logical value of the second signal S2 roughly indicates that similar waveforms are repeatedly arranged.

Unlike FIG. 2, the voltage variation Vdif increases from time t_dvdt before the last pulse of the pulse train of the signal J1 falls. As described above, during a rise period, the potential G2 is lower than the potential G1. Therefore, the reception signal VR1 rises without falling in correspondence with the fall. As a result, the potential difference between the reception signals VR1 and VR2 is smaller than the potential difference when the pulse in the signal J1 falls when the voltage variation Vdif is steady. As a result, the potential difference between the signals VRO1 and VRO2 is also small (not illustrated in FIG. 3), and hence the detection circuit 240 sometimes does not perform the above operation “(ii) lower the logical value of the second signal S2 from “H” to “L” in response to a change from a state where the subtraction voltage value ΔV is more than a negative second threshold value to a state where the subtraction voltage ΔV is equal to or less than the second threshold value”. Owing to such a malfunction, the logical value of the second signal S2 rises to “H” at time t_s and then maintains “H” even after time t_off (see the chain lines). A phenomenon in which the logical value of the second signal S2 maintains “H” for a period longer than that of “H” of the signal J1 owing to such a malfunction is referred to as “high latch” below for convenience.

The self-reset circuit 241 implements the above operation “(iv) set the logical value of the second signal S2 to “L” by resetting in preference to the operations in (i) to (iii) described above” in the detection circuit 240, thereby contributing to a reduction in high latch. FIG. 3 illustrates a case where the logical value of the second signal S2 becomes “L” at time t_d by resetting. In this case, the time interval from time t_s to time t_d corresponds to the allowable period. Such a reduction in high latch contributes to the second signal S2 appropriately reflecting the signal J1 and eventually to appropriately transmitting the first signal S1 to the second signal S2.

The allowable period is preferably longer than the pulse width adopted for each pulse generated by the signal J1. This is because even if there is no malfunction, a pulse reflecting the pulse is generated in the second signal S2, and if the allowable period is equal to or less than the pulse width, a normal operation is not performed. For example, the allowable period is equal to or less than one period of a pulse in the pulse train generated by the signal J1.

### <1-8. Clamp Circuits 205 and 206>

The clamp circuits 205 and 206 are connected in series between the input terminals P5 and P6. The potential G2 is applied to a connection point between the clamp circuits 205 and 206. The clamp circuit 205 is disposed closer to the input terminal P5 than the clamp circuit 206.

The clamp circuit 205 specifically includes, for example, diodes 201 and 202 and a resistor 207. In the clamp circuit 205, the diode 201 and the resistor 207 are connected in series. In the clamp circuit 205, the diode 202 and the resistor 207 are connected in series. The diodes 201 and 202 are connected in parallel with their forward directions reversed. The diode 202 is connected in parallel with the diode 201, and the forward direction thereof is opposite to the forward direction of the diode 201.

FIG. 1 illustrates a case where the forward direction of the diode 201 is a direction from the clamp circuit 206 toward the input terminal P5, and the forward direction of the diode 202 is a direction from the input terminal P5 toward the clamp circuit 206. For example, both the cathode of the diode 201 and the anode of the diode 202 are connected to the input terminal P5 via the resistor 207, and the potential G2 is applied to both the anode of the diode 201 and the cathode of the diode 202.

A current flowing through the parasitic capacitance Cp between the first end P1 side of the first coil 11 and the third end P3 side of the second coil 12 passes through the clamp circuit 205. The clamp circuit 205 contributes to the suppression of charging and discharging of the parasitic capacitance Cp. This suppression imposes limitations on an increase and a decrease in the potential of the third end P3 (which can also be said to be the potential taken by the reception signal VR1).

The clamp circuit 206 specifically includes, for example, diodes 203 and 204 and a resistor 208. In the clamp circuit 206, the diode 203 and the resistor 208 are connected in series. In the clamp circuit 206, the diode 204 and the resistor 208 are connected in series. The diodes 203 and 204 are connected in parallel with their forward directions reversed. The diode 204 is connected in parallel with the diode 203, and the forward direction thereof is opposite to the forward direction of the diode 203.

FIG. 1 illustrates a case where the forward direction of the diode 203 is a direction from the clamp circuit 205 toward the input terminal P6, and the forward direction of the diode 204 is a direction from the input terminal P6 toward the clamp circuit 205. For example, both the cathode of the diode 203 and the anode of the diode 204 are connected to the input terminal P6 via the resistor 208, and the potential G2 is applied to both the anode of the diode 203 and the cathode of the diode 204.

A current flowing through the parasitic capacitance Cp between the second end P2 side of the first coil 11 and the fourth end P4 side of the second coil 12 passes through the clamp circuit 206. The clamp circuit 206 contributes to the suppression of charging and discharging of the parasitic capacitance Cp. This suppression imposes limitations on an increase and a decrease in the potential of the fourth end P4 (which can also be said to be the potential taken by the reception signal VR2).

Either of the clamp circuits 205 and 206 contributes to a reduction in malfunction of the detection circuit 240 due to a variation in the potential difference between the potentials G1 and G2 (which can be represented by, for example, the above time derivative dv/dt).

Settings in the resistors 207 and 208 will be described in <2-6. Setting in Current Limiting Resistor> described later.

### <2. Power Conversion Apparatus>

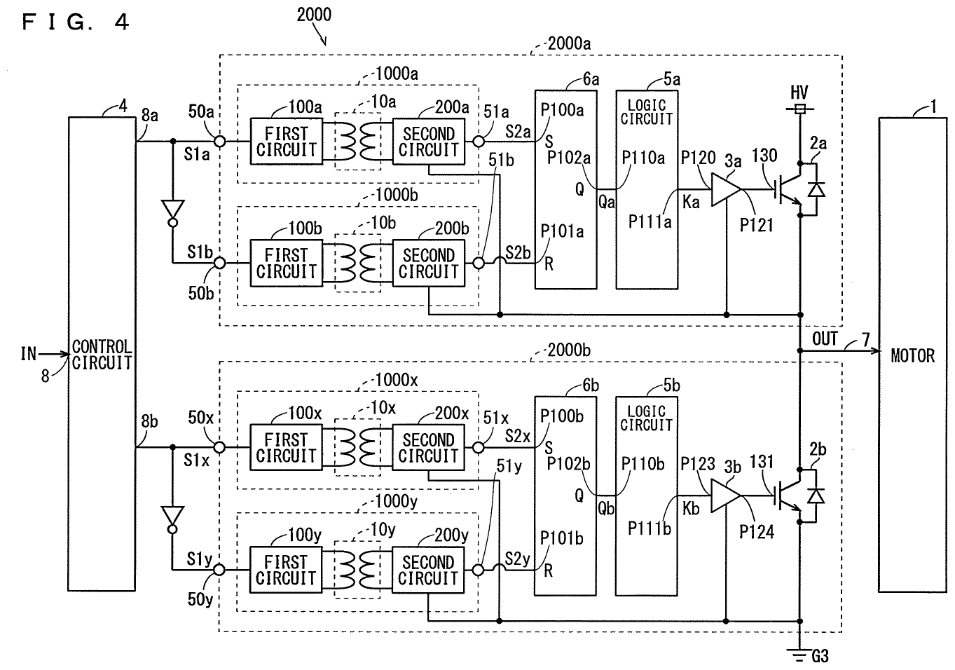

A second preferred embodiment of the present disclosure relates to a power conversion apparatus. FIG. 4 is a circuit diagram illustrating the configuration of a power conversion apparatus 2000 according to a second preferred embodiment.

First signals S1a, S1b, S1x, and S1y each having two logical values are input to the power conversion apparatus 2000. The power conversion apparatus 2000 outputs an output potential OUT to an external load 1 via an output line 7. The output potential OUT is the potential of the output line 7. The external load 1 is driven by the output potential OUT. The external load 1 is, for example, a motor.

An input signal IN is input to an input end 8 of a control circuit 4, the first signal S1a is output from an output end 8a, and the first signal S1x is output from an output end 8b. For example, the logical value of the first signal S1a is inverted by an inverter to obtain the first signal S1b. For example, the logical value of the first signal S1x is inverted by an inverter to obtain the first signal S1y.

A power conversion apparatus 2000 includes an upper arm circuit 2000a and a lower arm circuit 2000b. The upper arm circuit 2000a and the lower arm circuit 2000b are connected via an output line 7. It can also be seen that the output line 7 is provided in the power conversion apparatus 2000.

<2-1. Upper Arm Circuit 2000a>

The upper arm circuit 2000a includes signal transmission circuits 1000a and 1000b, a latch circuit 6a, a logic circuit 5a, a driver 3a, and a switching element 2a. For example, a power semiconductor switching element is adopted as the switching element 2a. For example, a reverse conducting insulated gate bipolar transistor IGBT (IGBT refers to an insulated gate bipolar transistor; the same applies hereinafter) 130 is adopted as the switching element 2a.

The signal transmission circuit 1000a includes an input terminal 50a, a first circuit 100a, a transformer 10a, a second circuit 200a, and an output terminal 51a. The input terminal 50a may be considered to be included in the first circuit 100a. The output terminal 51a may be considered to be included in the second circuit 200a.

The signal transmission circuit 1000b includes an input terminal 50b, a first circuit 100b, a transformer 10b, a second circuit 200b, and an output terminal 51b. The input terminal 50b may be considered to be included in the first circuit 100b. The output terminal 51b may be considered to be included in the second circuit 200b.

The first signal S1a is input to the input terminal 50a. The first signal S1b is input to the input terminal 50b. A second signal S2a is output from the output terminal 51a. A second signal S2b is output from the output terminal 51b.

The latch circuit 6a has a set end P100a, a reset end P101a, and an output end P102a. When the logical value of the signal input to the set end P100a takes “H”, the latch circuit 6a is set, and a signal Qa output from the output end P102a takes logical value “H”. When the logical value of the signal input to the reset end P101a takes “H”, the latch circuit 6a is reset, and the signal Qa takes logical value “L”.

The output terminal 51a is connected to the set end P100a, and the second signal S2a is input to the set end P100a. The output terminal 51b is connected to the reset end P101a, and the second signal S2b is input to the reset end P101a.

The logic circuit 5a has an input end P1i10a and an output end P111a. The input end P110a is connected to the output end P102a.

The driver 3a has an input end P120 and an output end P121. The input end P120 is connected to the output end P111a.

The gate of a reverse conducting IGBT 130 is connected to the output end P121. A fixed potential HV is applied to the collector of the reverse conducting IGBT 130 which is one end of the switching element 2a. The emitter of the reverse conducting IGBT 130, which is the other end of the switching element 2a, is connected to the output line 7. The gate of the reverse conducting IGBT 130 functions as an input end for driving the switching element 2a. A potential G3 serves as a reference for the potential HV. The potential G3 is, for example, a ground potential.

<2-2. Lower Arm Circuit 2000b>

The lower arm circuit 2000b includes signal transmission circuits 1000x and 1000y, a latch circuit 6b, a logic circuit 5b, a driver 3b, and a switching element 2b. For example, a power semiconductor switching element is adopted as the switching element 2b. For example, a reverse conducting IGBT 131 is adopted as the switching element 2b. A field effect transistor may be employed for either or both of the switching elements 2a and 2b.

The signal transmission circuit 1000x includes an input terminal 50x, a first circuit 100x, a transformer 10x, a second circuit 200x, and an output terminal 51x. The input terminal 50x may be considered to be included in the first circuit 100x. The output terminal 51x may be considered to be included in the second circuit 200x.

The signal transmission circuit 1000y includes an input terminal 50y, a first circuit 100y, a transformer 10y, a second circuit 200y, and an output terminal 51y. The input terminal 50y may be considered to be included in the first circuit 100y. The output terminal 51y may be considered to be included in the second circuit 200y.

The first signal S1x is input to the input terminal 50x. The first signal S1y is input to the input terminal 50y. The second signal S2x is output from the output terminal 51x. The second signal S2y is output from the output terminal 51y.

The latch circuit 6b has a set end P100b, a reset end P101b, and an output end P102b. When the logical value of the signal input to the set end P100b takes “H”, the latch circuit 6b is set, and a signal Qb output from the output end P102b takes logical value “H”. When the logical value of the signal input to the reset end P101b takes “H”, the latch circuit 6b is reset, and the signal Qb takes logical value “L”.

The output terminal 51x is connected to the set end P100b, and the second signal S2x is input to the set end P100b. The output terminal 51y is connected to the reset end P101b, and the second signal S2y is input to the reset end P101b.

The logic circuit 5b has an input end P110b and an output end P111b. The input end P110b is connected to the output end P102b.

The driver 3b has an input end P123 and an output end P124. The input end P123 is connected to the output end P111b.

The gate of the reverse conducting IGBT 131 is connected to the output end P124. The collector of the reverse conducting IGBT 131, which is one end of the switching element 2b, is connected to the output line 7. The potential G3 is applied to the emitter of the reverse conducting IGBT 131, which is the other end of the switching element 2b. The gate of the reverse conducting IGBT 131 functions as an input end for driving the switching element 2b.

<2-3. Signal Transmission Circuits 1000a, 1000b, 1000x, and 1000y>

Each of the signal transmission circuits 1000a, 1000b, 1000x, and 1000y according to the second preferred embodiment adopts, for example, the configuration of the signal transmission circuit 1000 according to the first preferred embodiment. The power conversion apparatus 2000 according to the second preferred embodiment can obtain the advantage of the signal transmission circuit 1000.

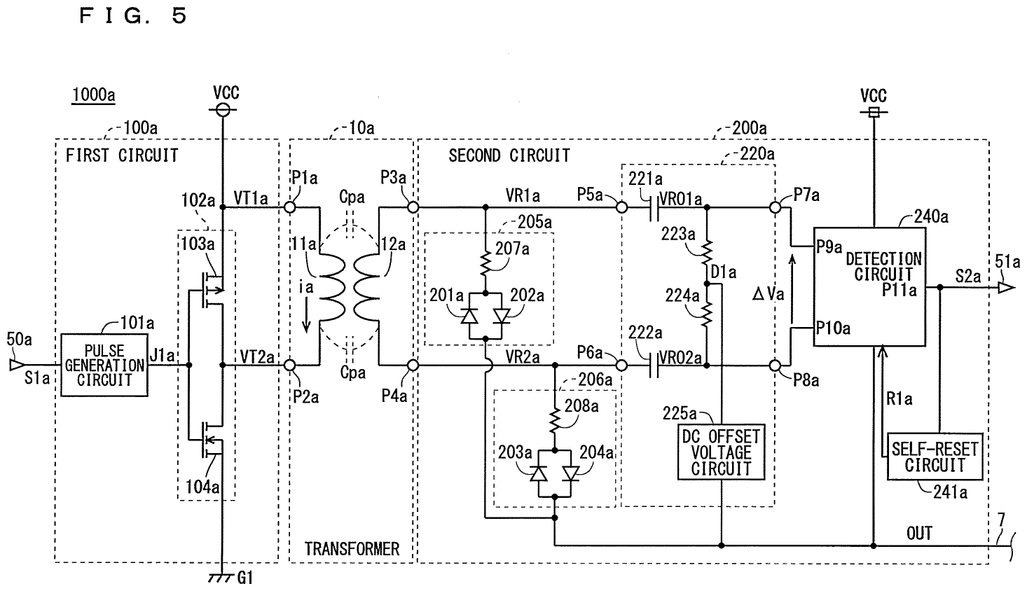

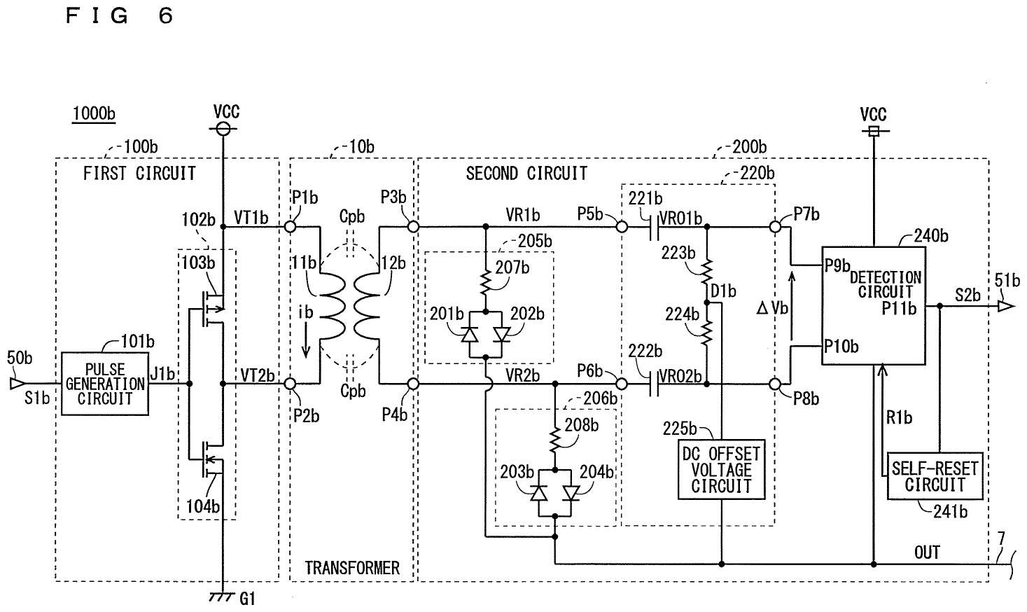

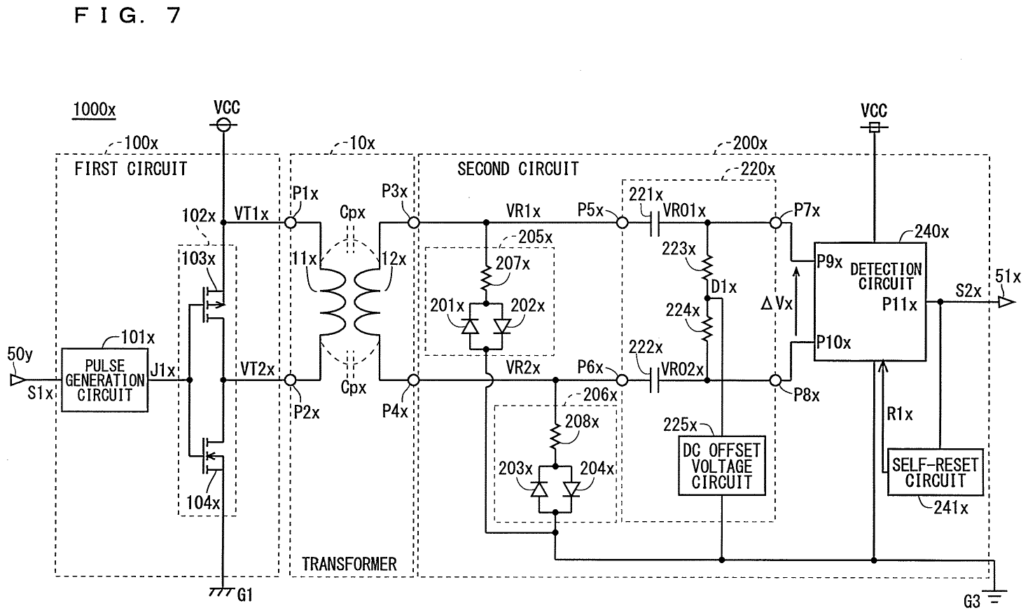

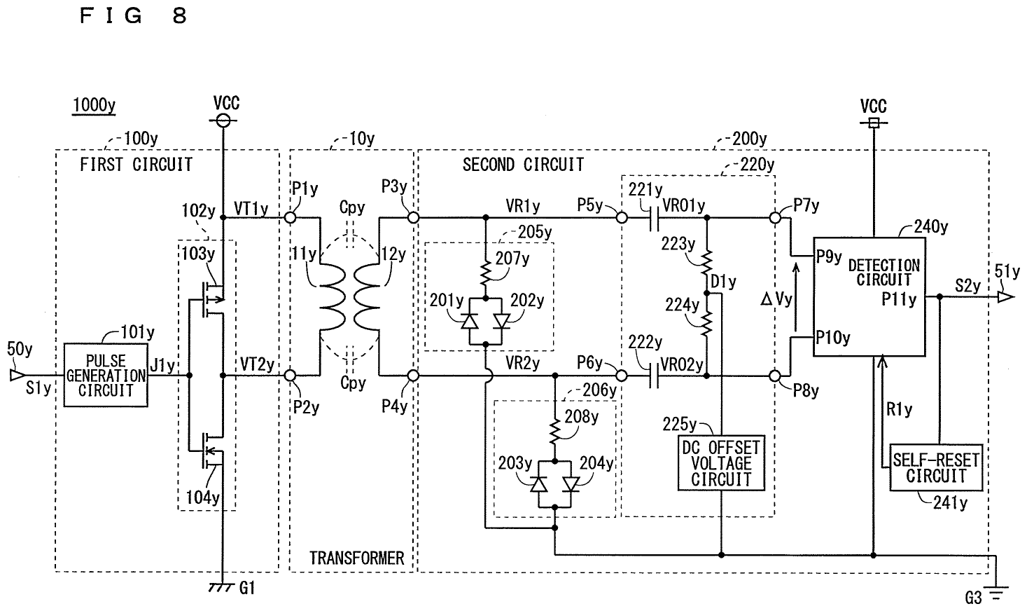

FIG. 5 is a circuit diagram illustrating the configuration of the signal transmission circuit 1000a. FIG. 6 is a circuit diagram illustrating the configuration of the signal transmission circuit 1000b. FIG. 7 is a circuit diagram illustrating the configuration of the signal transmission circuit 1000x. FIG. 8 is a circuit diagram illustrating the configuration of the signal transmission circuit 1000y.

The configuration of the signal transmission circuit 1000a (see FIG. 5) is the same as the signal transmission circuit 1000 (see FIG. 1) described in the first preferred embodiment except for the connection relationship with the output line 7. Specifically, the configuration and operation of the signal transmission circuit 1000a are explained by reading the first circuit 100, the pulse generation circuit 101, the output circuit 102, the transistors 103 and 104, the transformer 10, the first coil 11, the second coil 12, the input terminal 50, the output terminal 51, the second circuit 200, the diodes 201, 202, 203, and 204, the clamp circuits 205 and 206, the resistors 207 and 208, the offset circuit 220, the capacitors 221 and 222, the voltage dividing resistors 223 and 224, the DC offset voltage circuit 225, the detection circuit 240, the self-reset circuit 241, the first end P1, the second end P2, the third end P3, the fourth end P4, the input terminals P5 and P6, the output terminals P7 and P8, the input ends P9 and P10, the output end P11, the parasitic capacitance Cp, the first signal S1, the second signal S2, the signals J1, VRO1, and VRO2, the potential VT1, the transmission signal VT2, the reception signals VR1 and VR2, the DC voltage D1, the reset signal R1, and the subtraction voltage value ΔV, which are described in the first preferred embodiment, as the first circuit 100a, a pulse generation circuit 101a, an output circuit 102a, transistors 103a and 104a, the transformer 10a, a first coil 11a, a second coil 12a, the input terminal 50a, the output terminal 51a, the second circuit 200a, diodes 201a, 202a, 203a, and 204a, clamp circuits 205a and 206a, resistors 207a and 208a, an offset circuit 220a, capacitors 221a and 222a, voltage dividing resistors 223a and 224a, a DC offset voltage circuit 225a, a detection circuit 240a, a self-reset circuit 241a, a first end P1a, a second end P2a, a third end P3a, and a fourth end P4a, input terminals P5a and P6a, output terminals P7a and P8a, input ends P9a and P10a, an output end P11a, a parasitic capacitor Cpa, the first signal S1a, the second signal S2a, signals J1a, VRO1a, and VRO2a, a potential VT1a, a transmission signal VT2a, reception signals VR1a and VR2a, a DC voltage D1a, a reset signal R1a, and a subtraction voltage value ΔVa.

However, in the configuration of the signal transmission circuit 1000a, the output line 7 is connected to each of the anodes of the diodes 201a and 203a and the cathodes of the diodes 202a and 204a, and the output potential OUT is applied to each of them. The DC offset voltage circuit 225a outputs the DC voltage D1a with reference to the output potential OUT. The operating voltage of the detection circuit 240a is the potential difference between the potential VCC and the output potential OUT. The output potential OUT corresponds to the potential G2 in the first preferred embodiment.

The configuration of the signal transmission circuit 1000b (see FIG. 6) is the same as the configuration of the signal transmission circuit 1000a (see FIG. 5). Specifically, the configuration and operation of the signal transmission circuit 1000b are explained by reading the first circuit 100a, the pulse generation circuit 101a, the output circuit 102a, the transistors 103a and 104a, the transformer 10a, the first coil 11a, the second coil 12a, the input terminal 50a, the output terminal 51a, the second circuit 200a, the diodes 201a, 202a, 203a, and 204a, the clamp circuits 205a and 206a, the resistors 207a and 208a, the offset circuit 220a, the capacitors 221a and 222a, the voltage dividing resistors 223a and 224a, the DC offset voltage circuit 225a, the detection circuit 240a, the self-reset circuit 241a, the first end P1a, the second end P2a, the third end P3a, the fourth end P4a, the input terminals P5a and P6a, the output terminals P7a and P8a, the input ends P9a and P10a, the output end P11a, the parasitic capacitance Cpa, the first signal S1a, the second signal S2a, the signals J1a, VRO1a, and VRO2a, the potential VT1a, the transmission signal VT2a, the reception signals VR1a and VR2a, the DC voltage D1a, the reset signal R1a, and the subtraction voltage value ΔVa, which are included in the signal transmission circuit 1000a, as the first circuit 100b, a pulse generation circuit 101b, an output circuit 102b, transistors 103b and 104b, the transformer 10b, a first coil 11b, a second coil 12b, the input terminal 50b, the output terminal 51b, the second circuit 200b, diodes 201b, 202b, 203b, and 204b, clamp circuits 205b and 206b, resistors 207b and 208b, an offset circuit 220b, capacitors 221b and 222b, voltage dividing resistors 223b and 224b, a DC offset voltage circuit 225b, a detection circuit 240b, a self-reset circuit 241b, a first end P1b, a second end P2b, a third end P3b, and a fourth end P4b, input terminals P5b and P6b, output terminals P7b and P8b, input ends P9b and P10b, an output end P11b, a parasitic capacitor Cpb, the first signal S1b, the second signal S2b, signals J1b, VRO1b, and VRO2b, a potential VT1b, a transmission signal VT2b, reception signals VR1b and VR2b, a DC voltage Dib, a reset signal Rib, and a subtraction voltage value ΔVb.

The configuration of the signal transmission circuit 1000x (see FIG. 7) is the same as the signal transmission circuit 1000 (see FIG. 1) described in the first preferred embodiment except for the potentials G2 and G3. Specifically, the configuration and operation of the signal transmission circuit 1000x are explained by reading the first circuit 100, the pulse generation circuit 101, the output circuit 102, the transistors 103 and 104, the transformer 10, the first coil 11, the second coil 12, the input terminal 50, the output terminal 51, the second circuit 200, the diodes 201, 202, 203, and 204, the clamp circuits 205 and 206, the resistors 207 and 208, the offset circuit 220, the capacitors 221 and 222, the voltage dividing resistors 223 and 224, the DC offset voltage circuit 225, the detection circuit 240, the self-reset circuit 241, the first end P1, the second end P2, the third end P3, the fourth end P4, the input terminals P5 and P6, the output terminals P7 and P8, the input ends P9 and P10, the output end P11, the parasitic capacitance Cp, the first signal S1, the second signal S2, the signals J1, VRO1, and VRO2, the potential VT1, the transmission signal VT2, the reception signals VR1 and VR2, the DC voltage D1, the reset signal R1, the subtraction voltage value ΔV, and the potential G2, which are described in the first preferred embodiment, as the first circuit 100x, a pulse generation circuit 101x, an output circuit 102x, transistors 103x and 104x, the transformer 10x, a first coil 11x, a second coil 12x, the input terminal 50x, the output terminal 51x, the second circuit 200x, diodes 201x, 202x, 203x, and 204x, clamp circuits 205x and 206x, resistors 207x and 208x, an offset circuit 220x, capacitors 221x and 222x, voltage dividing resistors 223x and 224x, a DC offset voltage circuit 225x, a detection circuit 240x, a self-reset circuit 241x, a first end P1x, a second end P2x, a third end P3x, and a fourth end P4x, input terminals P5x and P6x, output terminals P7x and P8x, input ends P9x and P10x, an output end P11x, a parasitic capacitor Cpx, the first signal S1x, the second signal S2x, signals J1x, VRO1x, and VRO2x, a potential VT1x, a transmission signal VT2x, reception signals VR1x and VR2x, a DC voltage Dix, a reset signal R1x, a subtraction voltage value ΔVx, and the potential G3.

The configuration of the signal transmission circuit 1000y (see FIG. 8) is the same as the configuration of the signal transmission circuit 1000x (see FIG. 7). Specifically, the configuration and operation of the signal transmission circuit 1000y are explained by reading the first circuit 100x, the pulse generation circuit 101x, the output circuit 102x, the transistors 103x and 104x, the transformer 10x, the first coil 11x, the second coil 12x, the input terminal 50x, the output terminal 51x, the second circuit 200x, the diodes 201x, 202x, 203x, and 204x, the clamp circuits 205x and 206x, the resistors 207x and 208x, the offset circuit 220x, the capacitors 22ix and 222x, the voltage dividing resistors 223x and 224x, the DC offset voltage circuit 225x, the detection circuit 240x, the self-reset circuit 241x, the first end P1x, the second end P2x, the third end P3x, the fourth end P4x, the input terminals P5x and P6x, the output terminals P7x and P8x, the input ends P9x and P10x, the output end P11x, the parasitic capacitance Cpx, the first signal S1x, the second signal S2x, the signals J1x, VRO1x, and VRO2x, the potential VT1x, the transmission signal VT2x, the reception signals VR1x and VR2x, the DC voltage Dix, the reset signal Rix, and the subtraction voltage value ΔVx, which are included in the signal transmission circuit 1000x, as the first circuit 100y, a pulse generation circuit 101y, an output circuit 102y, transistors 103y and 104y, the transformer 10y, a first coil 11y, a second coil 12y, the input terminal 50y, the output terminal 51y, the second circuit 200y, diodes 201y, 202y, 203y, and 204y, clamp circuits 205y and 206y, resistors 207y and 208y, an offset circuit 220y, capacitors 221y and 222y, voltage dividing resistors 223y and 224y, a DC offset voltage circuit 225y, a detection circuit 240y, a self-reset circuit 241y, a first end P1y, a second end P2y, a third end P3y, and a fourth end P4y, input terminals P5y and P6y, output terminals P7y and P8y, input ends P9y and P10y, an output end P11y, a parasitic capacitor Cpy, the first signal S1y, the second signal S2y, signals J1y, VRO1y, and VRO2y, a potential VT1y, a transmission signal VT2y, reception signals VR1y and VR2y, a DC voltage D1y, a reset signal Rly, and a subtraction voltage value ΔVy.

Either of the signal transmission circuits 1000a, 1000b, 1000x, and 1000y according to the second preferred embodiment operate similarly to the signal transmission circuit 1000 according to the first preferred embodiment. However, the potential G2 in the signal transmission circuit 1000 corresponds to the output potential OUT in the signal transmission circuits 1000a and 1000b, and the potential G2 in the signal transmission circuit 1000 corresponds to the potential G3 in the signal transmission circuits 1000x and 1000y.

The potential G2 set when the signal transmission circuit 1000 is adopted as the signal transmission circuit 1000a is the output potential OUT. The potential G2 set when the signal transmission circuit 1000 is adopted as the signal transmission circuit 1000b is the output potential OUT. The potential G2 set when the signal transmission circuit 1000 is adopted as the signal transmission circuit 1000x is the potential G3. The potential G2 set when the signal transmission circuit 1000 is adopted as the signal transmission circuit 1000y is the potential G3.

For example, the input signal IN has information for driving the external load 1. The control circuit 4 generates the first signals S1a and S1x based on the input signal IN. For example, the first signals S1a and S1x exclusively take logical value “H” and are activated. The logical values of the first signals S1b and S1y are in an inverted relationship with the logical values of the first signals S1a and S1x, respectively. The following will exemplify a case where the potential corresponding to logical value “H” is higher than the potential corresponding to logical value “L”.

The signal transmission circuit 1000a performs signal transmission via the transformer 10a and outputs the second signal S2a. The signal transmission circuit 1000b performs signal transmission via the transformer 10b and outputs the second signal S2b. The signal transmission circuit 1000x performs signal transmission via the transformer 10x and outputs the second signal S2x. The signal transmission circuit 1000y performs signal transmission via the transformer 10y and outputs the second signal S2y.

The second signal S2a is input to the set end P100a. The second signal S2a takes logical value “H”, so that the signal Qa output from the output end P102a takes logical value “H”. The second signal S2b is input to the reset end P101a. The second signal S2b takes logical value “H”, so that the signal Qa takes logical value “L”.

As described above, similar to the relationship between the signal J1 and the second signal S2 described in the first preferred embodiment (see FIG. 2), the waveform of the logical value of the second signal S2a indicates a pulse train reflecting the pulse train of the logical value of the signal J1a. Therefore, the waveform of the logical value of the second signal S2a does not necessarily reflect the waveform of the logical value of the first signal Sla. However, owing to the function of the latch circuit 6a, after the second signal S2a once takes logical value “H”, the signal Qa continues to take logical value “H” until the second signal S2b takes logical value “H”. Similarly, after the second signal S2b once takes logical value “H”, the signal Qa continues to take logical value “L” until the second signal S2a takes logical value “H”. Since the logical value of the second signal S2b and the logical value of the second signal S2a are in an inverted relationship, the signal Qa takes a logical value reflecting the logical value of the first signal Sla.

Similar to the first signal S1a, the signal Qa functions as a drive-on signal that permits the switching element 2a to be turned on. Similarly to the first signal S1b, the signal Qa also functions as a drive-off signal that prohibits the switching element 2a from being turned on. The signal Qa controls permission or prohibition of conduction of the switching element 2a.

The second signal S2x is input to the set end P100b. The second signal S2x takes logical value “H”, so that the signal Qb output from the output end P102b takes logical value “H”. The second signal S2y is input to the reset end P101b. The second signal S2y takes logical value “H”, so that the signal Qb takes logical value “L”.

Owing to the function of the latch circuit 6b, the signal Qb takes a logical value reflecting the logical value of the first signal S1x. Similar to the first signal S1x, the signal Qb functions as a drive-on signal that permits the switching element 2b to be turned on. Similarly to the first signal S1y, the signal Qb also functions as a drive-off signal that prohibits the switching element 2b from being turned off. The signal Qb controls permission or prohibition of conduction of the switching element 2b.

The signal Qa is input to the input end P1i10a. The logic circuit 5a generates a signal Ka from the signal Qa and outputs the signal Ka from the output end P111a. The signal Qb is input to the input end P110b. The logic circuit 5b generates a signal Kb from the signal Qb and outputs the signal Kb from the output end P111b. The signal Kb is provided to the input end P123. The signal Ka is provided to the input end P120.

The driver 3a amplifies the signal Ka with a predetermined gain to drive the switching element 2a. The driver 3b amplifies the signal Kb with a predetermined gain to drive the switching element 2b.

The signal Qa functions as both a drive-on signal and a drive-off signal for the switching element 2a. When the signal Qa takes logical value “H”, for example, the logic circuit 5a modulates the signal Qa to generate the signal Ka. Similarly, when the signal Qb takes logical value “H”, for example, the logic circuit 5b modulates the signal Qb to generate the signal Kb, for example. For example, the signal Ka is intermittently activated when the signal Qa takes logical value “H” and is not activated when the signal Qa takes logical value “L”. For example, the signal Kb is intermittently activated when the signal Qb takes logical value “H” and is not activated when the signal Qb takes logical value “L”.

Since the logical values of the first signals S1a and S1x are exclusively set at “H” and the logical values of the signals Qa and Qb are also exclusively set at “H”, the signals Ka and Kb generated as described above do not simultaneously turn on the switching elements 2a and 2b when the second signals S2a, S2b, S2x, and S2y are normally obtained. The switching elements 2a and 2b are exclusively turned on but are not necessarily turned on complementarily.

When the on-resistance of the switching element 2a is ignored, turning on of the switching element 2a in a state where the switching element 2b is off results in the output potential OUT rises toward the potential HV. When the on-resistance of the switching element 2b is ignored, turning on of the switching element 2b in a state where the switching element 2a is off results in the output potential OUT decreases toward the potential G3.

The second circuit 200a of the signal transmission circuit 1000a, the second circuit 200b of the signal transmission circuit 1000b, and the driver 3a are all connected to the output line 7 and operate with the output potential OUT as a reference potential. The output potential OUT varies between the potential G3 and the potential HV in accordance with the time of the ON state of the switching elements 2a and 2b. The potential difference between the potentials G3 and HV is, for example, several hundred to several thousand V.

The control circuit 4 and the first circuits 100a, 100b, 100x, and 100y are not directly connected to the output line 7. The control circuit 4 is separated from the drivers 3a and 3b and the switching elements 2a and 2b in terms of direct current.

For example, even if the drivers 3a and 3b and the switching elements 2a and 2b are arranged in a high voltage region in consideration of the potential HV, the control circuit 4 can be arranged in a low voltage region separated from the high voltage region in terms of direct current. Such an arrangement contributes to the prevention of malfunction of the control circuit 4 and the prevention of electric shock.

### <2-4. Output Potential OUT as Reference for Potential of Second Circuit>

It is assumed that an event similar to the high latch of the second signal S2 caused by the malfunction of the detection circuit 240 in the second circuit 200 described with reference to FIG. 3 in the first exemplary preferred embodiment occurs in either or both of the second signals S2a and S2b. In such a case, both of the second signals S2a and S2b are set at “H”, and the signal Qa may not normally function as a drive-on signal such as the first signal S1a or a drive-off signal such as the first signal S1b. The same applies to the signal Qb.

The fact that the signals Qa and Qb do not normally function as a drive-on signal or a drive-off signal as described above may cause an event in which the switching elements 2a and 2b are simultaneously turned on. In order to avoid such an event, it is desirable that an event similar to the high latch of the second signal S2 does not occur in the second signals S2a, S2b, S2x, and S2y.

The power conversion apparatus 2000 adopts the signal transmission circuits 1000a, 1000b, 1000x, and 1000y, and each of the self-reset circuits 241a, 241b, 241x, and 241y in the second circuits 200a, 200b, 200x, and 200y included in the respective signal transmission circuits can operate similarly to the second circuit 200 in the signal transmission circuit 1000, thereby contributing to the prevention of the high latch in the second signals S2a, S2b, S2x, and S2y.

Therefore, in the power conversion apparatus 2000 according to the second preferred embodiment, malfunction of the switching elements 2a and 2b is suppressed.

### <2-5. Variation in Potential G2>

When the switching elements 2a and 2b are opened and closed, the output potential OUT varies between the potentials G3 and HV. The variation in the potential G2 described using the signal transmission circuit 1000 is caused by, for example, a variation in the output potential OUT when the signal transmission circuit 1000 is adopted as the signal transmission circuits 1000a and 1000b. Similar to the variation in the potential G2, the variation in the output potential OUT also introduces the time derivative dv/dt of the voltage.

For simplicity of explanation, the following will exemplify a case where the switching element 2b is turned off and the output potential OUT decreases toward the potential G3 (dv/dt<0) in a state where the switching element 2a is off. In a case where the switching element 2b is turned on and the output potential OUT rises toward the potential HV in a state where the switching element 2a is off, the sign of the time derivative dv/dt differs. The following will deal with an event caused by the time derivative dv/dt, and hence the following operation and effect can be obtained in any case by alternatively reading the flow direction of the displacement current depending on the sign of the time derivative dv/dt.

In addition, a description will be made assuming a case where the potentials G1 and G3 are equal. The following will deal with an event caused by the time derivative dv/dt. This assumption is based on a difference in DC voltage and does not have any influence on the time derivative dv/dt itself. Therefore, even in a case where the potentials G1 and G3 are different, the following effects can be obtained.

For example, an increase in the voltage variation Vdif in the signal transmission circuit 1000 illustrated in FIGS. 2 and 3 occurs before and after the trailing edge of the first signal S1 illustrated in FIGS. 2 and 3. The voltage variation Vdif is caused by, for example, the turn-off of the switching element 2b in response to a trailing edge of the first signal Sla when the signal transmission circuit 1000 is used as the signal transmission circuit 1000a.

However, the voltage variation Vdif illustrated in FIGS. 2 and 3 corresponds to an increase in voltage caused by the turn-off of the switching element 2b in response to one trailing edge of the logical value of the first signal S1a provided to the signal transmission circuit 1000a. The transition of the logical value of the first signal S1 illustrated in FIGS. 2 and 3 corresponds to the transition of the logical value of the first signal S1a generated after the first signal S1a having a trailing edge to which the turn-off responds.

The turn-off of the switching element 2b in response to a trailing edge of the logical value of a certain first signal S1a is delayed from the trailing edge due to the operation of the signal transmission circuit 1000a. Since a similar delay also occurs in the signal transmission circuit 1000, the above correspondence relationship may occur.

Similar to the voltage variation Vdif in the signal transmission circuit 1000, also in the signal transmission circuit 1000a, the potential of the third end P3a rises at −(dv/dt)·Cpa·Ra\hat{ }. Here, the symbol Cpa represents the electrostatic capacitance value of the parasitic capacitance Cpa, and the symbol Ra\hat{ } represents the resistance value of the equivalent resistance of the second circuit 200a. Similarly, also in the signal transmission circuit 1000b, the potential of the third end P3b rises at −(dv/dt)·Cpb·Rb\hat{ }. Here, the symbol Cpb indicates the electrostatic capacitance value of the parasitic capacitance Cpb, and the symbol Rb\hat{ } indicates the resistance value of the equivalent resistance of the second circuit 200b.

These rises may cause the high latches described in FIG. 3 and are desirably suppressed. For example, the parasitic capacitance Cpa is charged and discharged with the current represented by the product of the time derivative dv/dt and the electrostatic capacitance value of the parasitic capacitance Cpa, and the parasitic capacitance Cpb is charged and discharged with the current represented by the product of the time derivative dv/dt and the electrostatic capacitance value of the parasitic capacitance Cpb.

Also in the charging and discharging of the parasitic capacitance Cp by the clamp circuits 205 and 206 in the signal transmission circuit 1000, similarly to the charging and discharging of the parasitic capacitances Cpa and Cpb, the current represented by the product of the time derivative dv/dt and the electrostatic capacitance value of the parasitic capacitance Cp flows.

The parasitic capacitance Cpa is charged and discharged via either or both of the clamp circuits 205a and 206a. The parasitic capacitance Cpb is charged and discharged via either or both of the clamp circuits 205b and 206b. Similarly to the clamp circuits 205 and 206 in the signal transmission circuit 1000, the clamp circuits 205a and 206a contribute to the suppression of charging and discharging of the parasitic capacitance Cpa, and the clamp circuits 205b and 206b contribute to the suppression of charging and discharging of the parasitic capacitance Cpb.

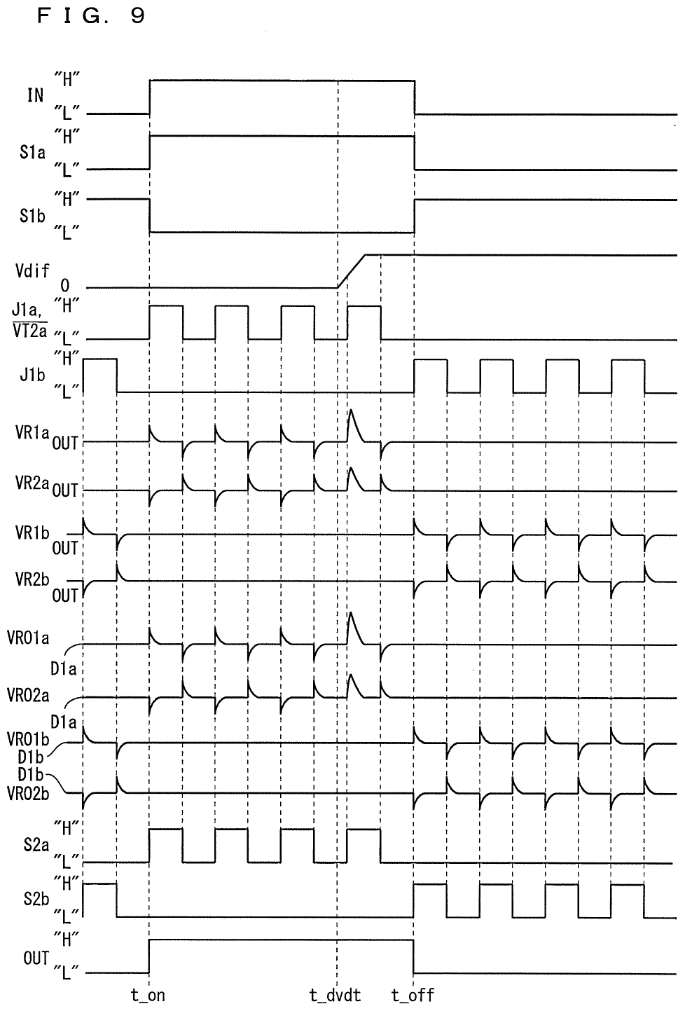

FIG. 9 is a waveform diagram illustrating temporal changes in various signals in the signal transmission circuits 1000a and 1000b. Specifically, FIG. 9 illustrates the waveforms of the logical value of the input signal IN, the logical values of the first signals S1a and S1b, the logical values of the signals J1a and J1b, the reception signals VR1a, VR2a, VR1b, and VR2b, the signals VRO1a, VRO2a, VRO1b, and VRO2b, the second signals S2a and S2b, and the logical value of the output potential OUT. FIG. 9 also illustrates the waveform of the voltage variation Vdif. FIG. 9 also illustrates an inversion of the logical value of the transmission signal VT2a together with the signal J1a by adding an overbar above the symbol “VT2a”.

The logical value of the input signal IN rises from “L” to “H” at time t_on. In response to this, the logical value of the first signal S1a also rises at time t_on, and the logical value of the first signal S1b falls from “H” to “L” at time t_on.

The logical value of the input signal IN falls from “H” to “L” at time t_off. In response to this, the logical value of the first signal S1a also falls at time t_off, and the logical value of the first signal S1b rises from “H” to “L” at time t_off.

The signal J1a outputs a pulse train in a period in which the logical value of the first signal S1a is at “H”. FIG. 9 illustrates a case where the signal J1a outputs four pulses in a period in which the logical value of the first signal S1a is at “H”. The signal J1b outputs a pulse train in a period in which the logical value of the first signal S1b is at “H”.

The reception signals VR1a, VR2a, VR1b, and VR2b all vary with reference to the output potential OUT. FIG. 9 illustrates the waveforms in which the reception signals VR1a and VR2a temporarily rise and fall, respectively, at the time when a pulse in the signal J1a rises, and attenuate thereafter. A current ia flowing through the first coil 11a and a mutual inductance La between the first coil 11a and the second coil 12a are introduced. The value of the reception signal VR1a is represented by La·(dia/dt), and the value of the reception signal VR2a is represented by −La·(dia/dt).

FIG. 9 illustrates the waveforms in which the reception signals VR1a and VR2a temporarily fall and rise, respectively, at the time when a pulse in the signal J1a falls, and attenuate thereafter. The value of the reception signal VR1a at this time is represented by −La·(dia/dt), and the value of the reception signal VR2a is represented by La·(dia/dt).

FIG. 9 illustrates the waveforms in which the reception signals VR1b and VR2b temporarily rise and fall, respectively, at the time when a pulse in the signal J1b rises, and attenuate thereafter. A current ib flowing through the first coil 11b and a mutual inductance Lb between the first coil 11b and the second coil 12b are introduced. The value of the reception signal VR1b is represented by Lb·(dib/dt), and the value of the reception signal VR2b is represented by −Lb·(dib/dt).

FIG. 9 illustrates the waveforms in which the reception signals VR1b and VR2b temporarily fall and rise, respectively, at the time when a pulse in the signal J1b falls, and attenuate thereafter. The value of the reception signal VR1b at this time is represented by −Lb·(dib/dt), and the value of the reception signal VR2b is represented by Lb·(dib/dt).

Similarly to FIG. 2, the voltage variation Vdif starts to rise from time t_dvdt. FIG. 9 illustrates the waveforms in which both the reception signals VR2a and VR1a rise at the time when a pulse in the signal J1a rises in a rise period and attenuates thereafter. Since no pulse train occurs in the signal J1b during a rise period, such an exceptional waveform does not occur in the reception signal VR2b.

The signals VRO1a, VRO2a, VRO1b, and VRO2b have waveforms similar to the waveforms of the reception signals VR1a, VR2a, VR1b, and VR2b, respectively. Owing to the high-pass filter obtained by the capacitor 221a and the voltage dividing resistor 223a and the DC offset voltage circuit 225a, the signal VRO1a exhibits a rise, a subsequent decay, a fall, and a subsequent decay similar to the reception signal VR1a with reference to the DC voltage D1a. Owing to the high-pass filter obtained by the capacitor 222a and the voltage dividing resistor 224a and the DC offset voltage circuit 225a, the signal VRO2a exhibits a rise and a subsequent decay similar to the reception signal VR2a with reference to the DC voltage D1a. Owing to the high-pass filter obtained by the capacitor 221b and the voltage dividing resistor 223b and the DC offset voltage circuit 225b, the signal VRO1b exhibits a rise, a subsequent decay, a fall, and a subsequent decay similar to the reception signal VR1b with reference to the DC voltage D1b. Owing to the high-pass filter obtained by the capacitor 222b and the voltage dividing resistor 224b and the DC offset voltage circuit 225b, the signal VRO2b exhibits a rise and a subsequent decay similar to the reception signal VR2b with reference to the DC voltage D1b.

FIG. 9 illustrates a case where the influence of the voltage variation Vdif on the subtraction voltage value ΔVa (the potential difference between the signal VRO1a and the signal VRO2a, specifically, the value obtained by subtracting the potential of the signal VRO2a from the potential of the signal VRO1a) is small even in a rise period, and the subtraction voltage value changes from a state of being less than the first threshold value to a state of being equal to or greater than the first threshold value. A case where the logical value of the second signal S2a rises from “L” to “H” according to operation (i) described above is exemplified.

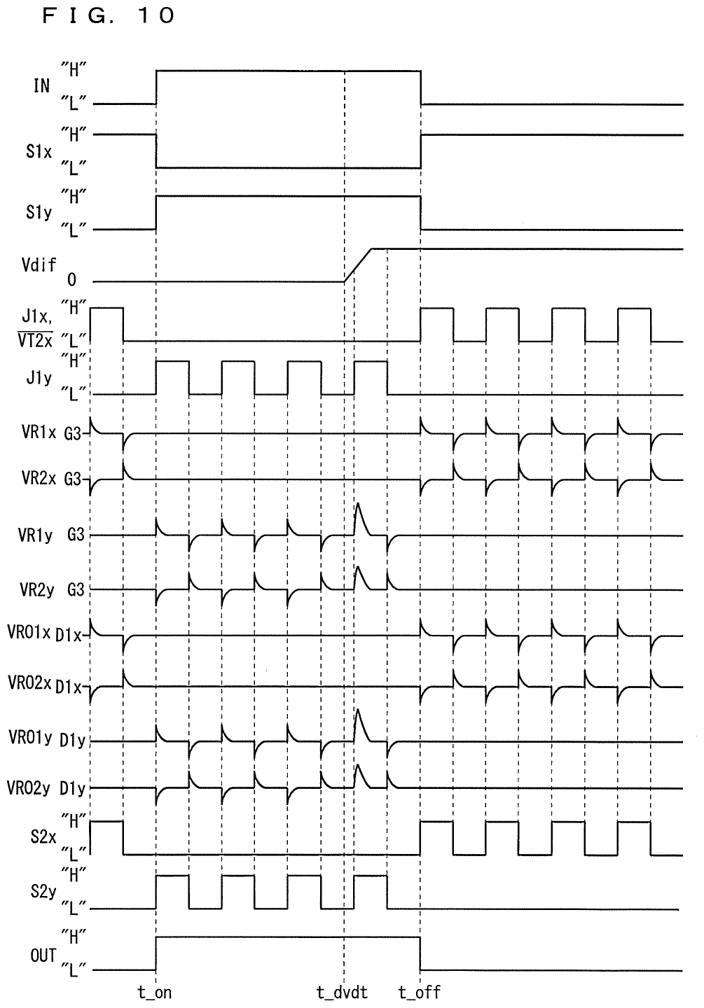

FIG. 10 is a waveform diagram illustrating temporal changes in various signals in the signal transmission circuits 1000x and 1000y. Specifically, FIG. 10 illustrates the waveforms of the logical value of the input signal IN, the logical values of the first signals S1x and S1y, the logical values of the signals J1x and J1y, the reception signals VR1x, VR2x, VR1y, and VR2y, the signals VRO1x, VRO2x, VRO1y, and VRO2y, the second signals S2x and S2y, and the logical value of the output potential OUT. FIG. 10 also illustrates an inversion of the logical value of the transmission signal VT2x together with the signal J1x by adding an overbar above the symbol “VT2x”.

For example, since the first signals S1a and S1x exclusively take logical value “H” and are activated, the waveforms of the logical values of the first signals S1x and S1y in FIG. 10 transition similarly to the waveforms of the logical values of the first signals S1b and S1a in FIG. 9, respectively.

Therefore, the waveforms of the logical values of the signals J1x and J1y, the reception signals VR1x, VR2x, VR1y, and VR2y, the signals VRO1x, VRO2x, VRO1y, and VRO2y, and the logical values of the second signals S2x and S2y in FIG. 10 appear similarly to the waveforms of the logical values of the signals J1b and J1a, the reception signals VR1b, VR2b, VR1a, and VR2a, the signals VRO1b, VRO2b, VRO1a, and VRO2a, and the second signals S2b and S2a in FIG. 10, respectively.

FIG. 10 illustrates a case where the influence of the voltage variation Vdif on the subtraction voltage value ΔVy (the potential difference between the signal VRO1y and the signal VRO2y, specifically, the value obtained by subtracting the potential of the signal VRO2y from the potential of the signal VRO1y) is small even in a rise period, and the subtraction voltage value changes from a state of being less than the first threshold value to a state of being equal to or greater than the first threshold value. A case where the logical value of the second signal S2y rises from “L” to “H” according to operation (i) described above is exemplified.

However, since the signal transmission circuits 1000x and 1000y use the potential G3 as a reference for potential, the reception signals VR1x, VR2x, VR1y, and VR2y vary with respect to the potential G3. Since the DC offset voltage circuit 225x outputs the DC voltage D1x with reference to the potential G3, the signals VRO1x and VRO2x vary with reference to the DC voltage D1x. Since the DC offset voltage circuit 225y outputs the DC voltage D1y with reference to the potential G3, the signals VRO1y and VRO2y vary with reference to the DC voltage D1y.

At time t_on, the logical value of the second signal S2b is at “L” (see FIG. 9), and the rising of the logical value of the second signal S2a causes the logical value of the signal Qa (not illustrated) to be at “H”. The logical value of the second signal S2x is at “L” (see FIG. 10), and the rising of the logical value of the second signal S2y causes the logical value of the signal Qb (not illustrated) to be at “L”. The logical value of the output potential OUT is set at “H”.

At time t_off, the logical value of the second signal S2a is at “L” (see FIG. 9), and the rising of the logical value of the second signal S2b causes the signal Qa (not illustrated) to be at “L”. The logical value of the second signal S2y is at “L” (see FIG. 10), and the rising of the logical value of the second signal S2x causes the signal Qb (not illustrated) to be at “H”. The logical value of the output potential OUT is set at “L”.

As described above, when the subtraction voltage value is less affected by the voltage variation Vdif, the logical value of the input signal IN is reflected in the logical value of the output potential OUT.

### <2-6. Settings in Current Limiting Resistor>

It can be said that the resistor 207a in the clamp circuit 205a in the signal transmission circuit 1000a is a current limiting resistor that limits the magnitude of a current flowing through the diodes 201a and 202a and contributing to charging and discharging of the parasitic capacitance Cpa. Similarly, it can be said that the resistor 208a in the clamp circuit 206a is a current limiting resistor that limits the magnitude of a current flowing through the diodes 203a and 204a and contributing to charging and discharging of the parasitic capacitance Cpa. Similarly, it can be said that all of the resistors 207b and 208b in the signal transmission circuit 1000b, the resistors 207x and 208x in the signal transmission circuit 1000x, the resistors 207y and 208y in the signal transmission circuit 1000y, and the resistor 207, 208 in the signal transmission circuit 1000 are current limiting resistors.

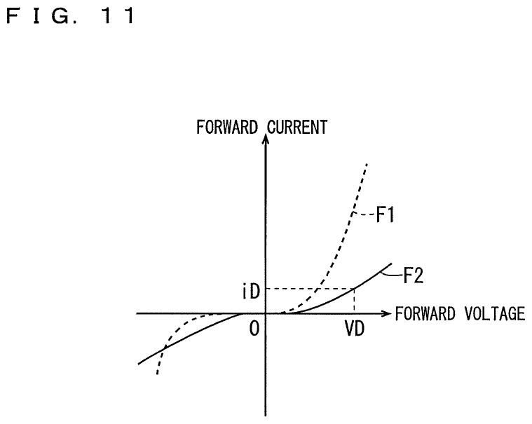

FIG. 11 is a graph illustrating the rectification characteristics of a diode. The abscissa indicates a forward voltage, and the ordinate indicates a forward current. The diode can be adopted as any of the diodes 201a, 202a, 203a, 204a, 201b, 202b, 203b, 204b, 201x, 202x, 203x, 204x, 201y, 202y, 203y, and 204y. A curve F1 indicates a current flowing through the diode when no current limiting resistor is provided, and a curve F2 indicates a current flowing through the diode when a current limiting resistor is provided.

In a case where a current limiting resistor is provided, the forward current iD flows when the forward voltage VD is applied to the diode. As can be seen from the comparison between the curves F1 and F2, the forward current decreases by providing a current limiting resistor. A current flowing through the clamp circuit 206a corresponds to any of the forward current iD flowing through the diode 201a and the forward current iD flowing through the diode 202a. A current flowing at the charging and discharging of the parasitic capacitance Cpa is the product of the electrostatic capacitance value of the parasitic capacitance Cpa and the time derivative (dv/dt). Therefore, setting the resistor 207a according to the assumed value of the time derivative (dv/dt) limits the displacement current for charging and discharging the parasitic capacitance Cpa, and thus, reduces the influence of the voltage variation Vdif on the reception signals VR1a and VR2a, and contributes to the suppression of the malfunction of the detection circuit 240a. Setting the resistor 208a in the same manner contributes to the suppression of the malfunction of the detection circuit 240b.

For example, when the output potential OUT decreases due to the turn-on of the switching element 2b, a displacement current flowing through the diode 202a of the clamp circuit 205a and the diode 204a of the clamp circuit 206a to discharge the parasitic capacitance Cpa is limited, and the influence of the voltage variation Vdif on the reception signals VR1a and VR2a is reduced, which contributes to the suppression of the malfunction of the detection circuit 240a. The displacement current flowing through the diode 202b of the clamp circuit 205b and the diode 204b of the clamp circuit 206b to discharge the parasitic capacitance Cpb is limited, and the influence of the voltage variation Vdif on the reception signals VR1b and VR2b is reduced, which contributes to the suppression of the malfunction of the detection circuit 240b.

When the output potential OUT increases due to the turn-on of the switching element 2a as well, a displacement current flowing through the diode 201a of the clamp circuit 205a and the diode 203a of the clamp circuit 206a to charge the parasitic capacitance Cpa is limited, and the influence of the voltage variation Vdif on the reception signals VR1a and VR2a is reduced, which contributes to the suppression of the malfunction of the detection circuit 240a. The displacement current flowing through the diode 201b of the clamp circuit 205b and the diode 203b of the clamp circuit 206b to charge the parasitic capacitance Cpb is limited, and the influence of the voltage variation Vdif on the reception signals VR1b and VR2b is reduced, which contributes to the suppression of the malfunction of the detection circuit 240b.

Similarly, the displacement current flowing through the diode 201x of the clamp circuit 205x and the diode 203x of the clamp circuit 206x to charge the parasitic capacitance Cpx is limited, and the influence of the voltage variation Vdif on the reception signals VR1x and VR2x is reduced, which contributes to the suppression of the malfunction of the detection circuit 240x. The displacement current flowing through the diode 202x of the clamp circuit 205x and the diode 204x of the clamp circuit 206x to discharge the parasitic capacitance Cpx is limited, and the influence of the voltage variation Vdif on the reception signals VR1x and VR2x is reduced, which contributes to the suppression of the malfunction of the detection circuit 240x.

Similarly, the displacement current flowing through the diode 201y of the clamp circuit 205y and the diode 203y of the clamp circuit 206y to charge the parasitic capacitance Cpy is limited, and the influence of the voltage variation Vdif on the reception signals VR1y and VR2y is reduced, which contributes to the suppression of the malfunction of the detection circuit 240y. The displacement current flowing through the diode 202y of the clamp circuit 205y and the diode 204y of the clamp circuit 206y to discharge the parasitic capacitance Cpy is limited, and the influence of the voltage variation Vdif on the reception signals VR1y and VR2y is reduced, which contributes to the suppression of the malfunction of the detection circuit 240y.

The settings of the resistors 207a, 208a, 207b, 208b, 207x, 208x, 207y, and 208y contribute to the suppression of the malfunction of the detection circuits 240a, 240b, 240x, and 240y and hence contribute to the output potential OUT appropriately reflecting the input signal IN.

Similarly, also in the signal transmission circuit 1000, setting the resistors 207 and 208 in accordance with the assumed value of the time derivative (dv/dt) limits the displacement current for charging and discharging the parasitic capacitance Cp. Such limitation contributes to a reduction in the influence of the voltage variation Vdif on the reception signals VR1 and VR2, and thus, the suppression of malfunction of the detection circuit 240. Such contribution contributes to the second signal S2 appropriately reflecting the signal J1, and thus, appropriately transmitting the first signal S1 to the second signal S2.

However, when the time derivative (dv/dt) exceeds an assumed value, the displacement current caused by the time derivative (dv/dt) may be larger than the charge and discharge current flowing as the forward current iD set by the current limiting resistor described above. In this case, the high latch described in FIG. 3 may also occur in the signal transmission circuits 1000a, 1000b, 1000x, and 1000y.

Similarly to the self-reset circuit 241 in the signal transmission circuit 1000 contributing to the avoidance of high latch, the self-reset circuits 241a, 241b, 241x, and 241y contribute to the avoidance of high latch in the signal transmission circuits 1000a, 1000b, 1000x, and 1000y, respectively, and hence contributing to the output potential OUT appropriately reflecting the input signal IN.

Note that the self-reset circuits 241a, 241b, 241x, and 241y contribute to the avoidance of high latch in the detection circuits 240a, 240b, 240x, and 240y, respectively, but do not directly influence the waveform of the output potential OUT. This is because the second signals S2a and SS2b are inputs to the latch circuit 6a, the second signals S2x and S2y are inputs to the latch circuit 6b, and the logical value of the output potential OUT is based on the logical value of the signal Qa output from the latch circuit 6a and the logical value of the signal Qb output from the latch circuit 6b.

For example, in the case of the upper arm circuit 2000a, it is assumed that high latch has occurred in the detection circuit 240a, that is, the logical value of the second signal S2a maintains “H” even after the logical value of the first signal S1a transitions from “H” to “L” and the logical value of the first signal S1b transitions from “L” to “H”. At this time, both of the second signals S2a and S2b take logical value “H” and the logical value of the signal Qa becomes uncertain, so that the logical value of the output potential OUT may be maintained at “H”.

However, thereafter, when the logical value of the first signal S1a transitions from “L” to “H” and the logical value of the first signal S1b transitions from “H” to “L”, the signal J1a newly generates a pulse train in a state where the logical value of the second signal S2b is at “L”. Due to the falling of a pulse included in the pulse train, the logical value of the second signal S2a takes “L”, and the logical value of the output potential OUT takes “L”. This reduces the influence that causes the external load 1 to malfunction.

### <3. Modifications of Pulse Train>

A third preferred embodiment of the present disclosure relates to modifications of the pulse trains in the signals J1, J1a, J1b, J1x, and J1y. Hereinafter, first, the pulse train in signal J1a will be described.

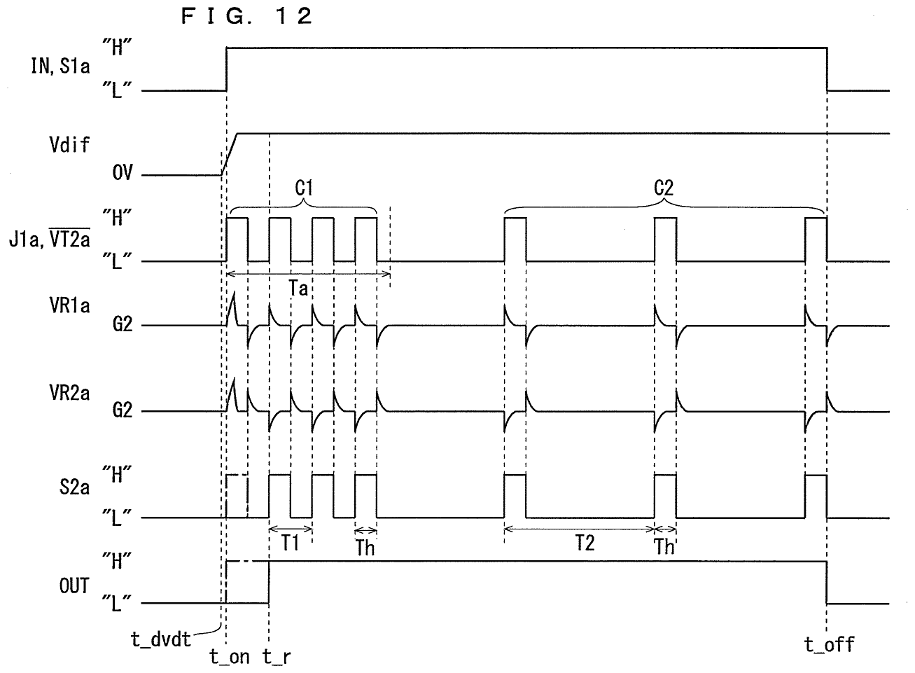

FIG. 12 is a waveform diagram illustrating various signals in a third preferred embodiment. FIG. 12 illustrates the waveforms of the logical value of an input signal IN, the logical value of the signal J1a, reception signals VR1a and VR2a, the logical value of a second signal S2a, and the logical value of an output potential OUT. FIG. 12 also illustrates the waveform of a voltage variation Vdif. The logical value of the input signal IN is the same as the logical value of a first signal S1a (see FIG. 9), and both are shown together in FIG. 12.

The logical value of the input signal IN rises from “L” to “H” at time t_on and falls from “H” to “L” at time t_off. The voltage variation Vdif starts increasing at time t_dvdt before time t_on and is also increasing at time t_on. Due to the falling of the logical value of the input signal IN generated before time t_on, the voltage variation Vdif may start to rise before time t_on.

According to the logical value of the signal J1a, a pulse train is generated in a period in which the logical value of the first signal S1a is at “H”. Referring to FIG. 12, the first pulse of the logical value of the signal J1a rises at time t_on. At the leading edge, if there is no influence of the voltage variation Vdif, the reception signal VR1a rises and the reception signal VR2a falls. However, FIG. 12 illustrates a case where the reception signal VR2a also rises due to the influence of the voltage variation Vdif rising at time t_on, and the subtraction voltage value does not exceed a first threshold.

Due to the influence of the voltage variation Vdif described above, the second signal S2a maintains “L” without reflecting the first pulse of the signal J1a. Referring to FIG. 12, a pulse generated in the logical value of the second signal S2a when there is no influence of the voltage variation Vdif is indicated by a chain line.

The second pulse of the logical value of the signal J1a rises at time t_r. At time t_r, the voltage variation Vdif is in a steady state, and neither of the reception signals VR1a and VR2a is influenced by the voltage variation Vdif. At time t_r, the reception signal VR1a rises, the reception signal VR2a falls, and the logical value of the second signal S2a rises. A pulse reflecting the pulse train of the logical value of the signal J1a is generated in the logical value of the subsequent second signal S2a.

The logical value of the output potential OUT rises in response to a leading edge of the logical value of the second signal S2a. When the logical value of the second signal S2a reflects the first pulse of the logical value of the signal J1a (see the pulse indicated by the chain line), the logical value of the output potential OUT rises at time t_on (see the chain line). Due to the influence of the voltage variation Vdif, the logical value of the output potential OUT rises at time t_r.

The logical value of the output potential OUT falls in response to a leading edge of the logical value of the second signal S2b (not illustrated). For example, in the second signal S2b, since a pulse train is generated in response to a trailing edge of the input signal IN (see FIG. 9), FIG. 12 illustrates a case where the logical value of the output potential OUT falls at time t_off.

Since it is desirable that a leading edge of the logical value of the output potential OUT appropriately reflects a leading edge of the logical value of the input signal IN, when the first pulse of the pulse train of the logical value of the signal J1a is not reflected in the logical value of the second signal S2a, it is desirable that the pulse generated subsequently is reflected in the logical value of the second signal S2a. From such a viewpoint, the occurrence of a pulse train including a plurality of pulses in the logic value of the signal J1a contributes to the logic value of the second signal S2a appropriately reflecting the logic value of the signal J1a, and thus, to the output potential OUT appropriately reflecting the input signal IN, particularly at its leading edge.

If the voltage variation Vdif is increasing also at the time when the second pulse rises (time t_r in view of FIG. 12), there is a possibility that the pulse is not reflected in the logical value of the second signal S2a. When the rise period is long, the number of pulses generated in the rise period is large among the pulse trains generated in the logical value of the signal J1a. From such a viewpoint, a pulse train may be continuously generated in the logical value of the signal J1a during a period in which the logical value of the input signal IN maintains “H”, and thus, the logical value of the first signal S1a maintains “H”.

However, the malfunction in which the waveform of the reception signal VR2a is distorted by the voltage variation Vdif and the subtraction voltage value does not exceed the first threshold does not necessarily occur corresponding to all the pulses that rise in a rise period. A displacement current derived from the voltage variation Vdif tends to be smaller as the rise period is longer. This is because the smaller a parasitic capacitance Cpa, the smaller the total amount of displacement current, and the longer the rise period, the smaller the voltage variation Vdif.

Therefore, even if a rise period is assumed to be long, it is not necessary to generate a pulse train over the entire rise period. On the other hand, the voltage variation Vdif having a short rise period generates a large displacement current. Therefore, a pulse generation circuit 101a generates a pulse train C1 in the signal J1a until an assumed value Ta elapses from time t_on at which the first signal S1a rises. The assumed value Ta is set to be equal to or longer than a length assumed as a rise period of the voltage variation Vdif that causes a displacement current having the minimum value that causes malfunction.

A number N of pulses in the pulse train C1 is introduced, and there is the relationship given by (N−1)·T1+Th<Ta<N·T1 (N=4 in FIG. 12) between the assumed value Ta, one period T1 of a pulse, and a period length Th in which the pulse is at “H”.

For example, when it is assumed that the potential difference between potentials HV and G3 is 1200 V and the time derivative (dv/dt) is 100 kV/μs, the assumed value Ta is set to 1200 V/(100 kV/μs)=12 ns.

After the assumed value Ta has elapsed from time t_on, the pulse generation circuit 101a may generate a pulse train (to be temporarily referred to as a “second pulse train”; a pulse train from time t_on until the assumed value Ta elapses is also temporarily referred to as a “first pulse train” hereinafter) C2 in the signal J1a. The generation of the second pulse train C2 is desirable from the viewpoint of enhancing the reliability of the signal transmission from the input signal IN to the output potential OUT.

It can be said that the first pulse train C1 has a plurality of pulses generated in a part of the period in which the logical value of the signal J1a takes “H”, and the second pulse train C2 has a plurality of pulses generated following the first pulse train C1 in the part. The assumed value Ta is adopted as the length of the part.

It is desirable not to generate the second pulse train C2 from the viewpoint of reducing the current consumption. In addition, even in a case where the second pulse train C2 is generated in the logical value of the signal J1a, making the generation frequency lower than that of the first pulse train C1 contributes to a reduction in current consumption. For example, one period T2 of a pulse in the second pulse train C2 is longer than one period T1 of a pulse in the first pulse train C1. FIG. 12 exemplifies a case where a pulse of the second pulse train C2 is also at “H” with the length of the period length Th.

Also with regard to the logical value of the signal J1b, the pulse generation circuit 101b generates a pulse train from time t_off (see FIG. 9) when the logical value of a first signal S1b rises until an assumed value Tb elapses. The assumed value Tb is set to be equal to or longer than a length assumed as a rise period of the voltage variation Vdif that causes a displacement current having the minimum value that causes malfunction.

A number M of pulses in the pulse train is introduced, and there is the relationship given by (M−1)·T1+Th<Tb<M·T1 between the assumed value Tb, one period T1 of a pulse, and a period length Th in which the pulse is at “H”.

Similarly to the case of the second pulse train C2, it is desirable that the pulse generation circuit 101b generates a pulse train in the signal J1b after the assumed value Tb has elapsed from time t_off from the viewpoint of enhancing the reliability of the signal transmission from the input signal IN to the output potential OUT. The fact that the period of the pulse train is longer than the period of the pulse train generated from time t_off until the assumed value Tb elapses contributes to a reduction in current consumption.

The pulse trains in the signals J1x and J1y can be modified similarly to the pulse trains in the signals J1b and J1a. Similarly, a modification similar to the pulse train in the signal J1a can be applied to the signal J1.

### <4. First Modification of First Circuit>

A fourth preferred embodiment of the present disclosure relates to a first modification of each of the first circuits 100, 100a, 100b, 100x, and 100y. The first modification of the first circuit 100 will be described first below.

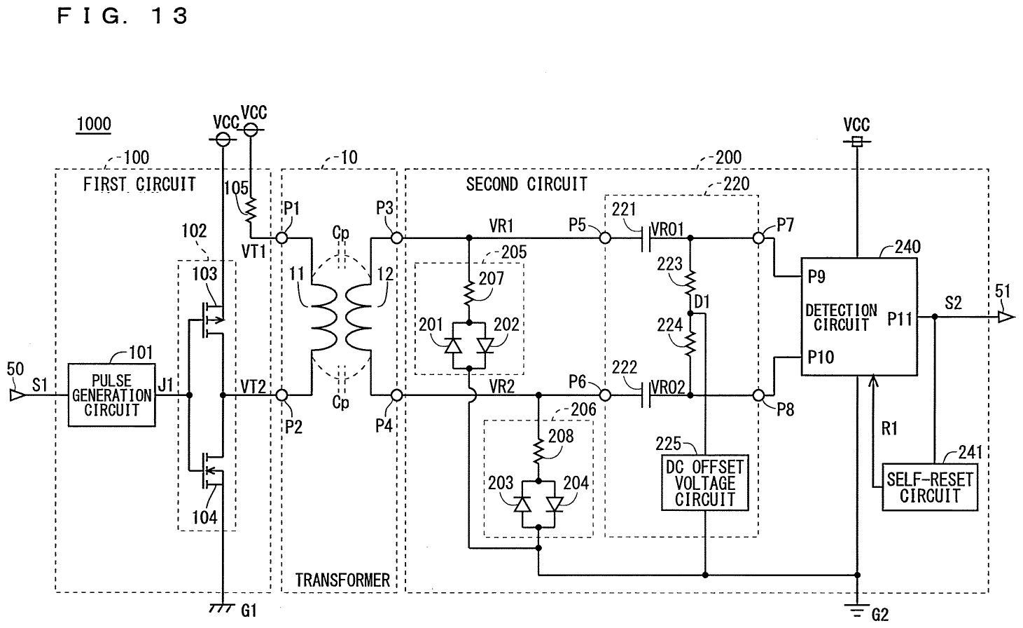

FIG. 13 is a circuit diagram illustrating the configuration of the signal transmission circuit 1000 to which the first modification of the first circuit 100 is applied.

In the first modification, the first circuit 100 further includes a resistor 105. The resistor 105 includes one end connected to a first end P1 and the other end to which a potential VCC is applied. In the first circuit 100 illustrated in FIG. 1, the source of the transistor 103 is connected to the first end P1, but in the first modification, the one end of the resistor 105 is connected to the first end P1. A potential VT1 is a potential at the other end of the resistor 105 and is output from the first circuit 100 to the first end P1.

As the resistance value of the resistor 105, a value approximate to the resistance value of the on-resistance of the transistor 103 (to be tentatively referred to as “on-resistance value” hereinafter), specifically, for example, a value of 90% to 110% of the on-resistance value, desirably, a value of 95% to 105% of the on-resistance value is adopted. When a potential G2 serving as a reference for a second circuit 200 becomes higher than a potential G1 serving as a reference for the first circuit 100 due to the influence of a voltage variation Vdif, a displacement current flows through the first circuit 100.

The approximation of the resistance value of the resistor 105 to the on-resistance value of the transistor 103 reduces the difference between the displacement current flowing through one end of the first coil 11 and the first end P1 and the displacement current flowing through the other end of the first coil 11 and the second end P2, thereby contributing to preventing the malfunction (to be described later) due to the difference. From this viewpoint, the wiring resistance from the power supply (not illustrated) that applies the potential VCC to the other end of the resistor 105 to the first end P1 is desirably equal to the wiring resistance from the second end P2 to the power supply (not illustrated) that applies the potential G1 to the source of the transistor 104.

Even if the resistance value of the resistor 105 is different from the on-resistance value of the transistor 103, the effect of reducing the difference between these two types of displacement currents can be obtained even if there is a difference in effect due to the degree of the difference.

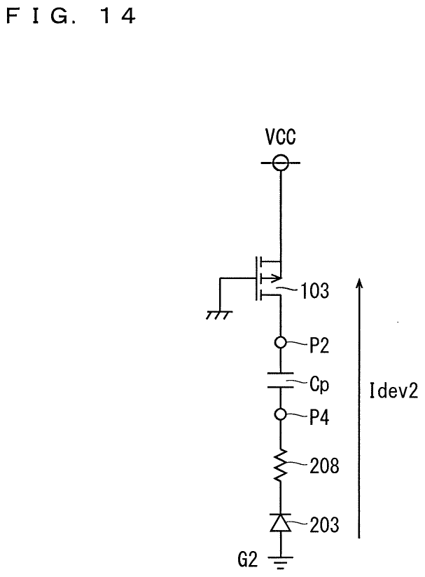

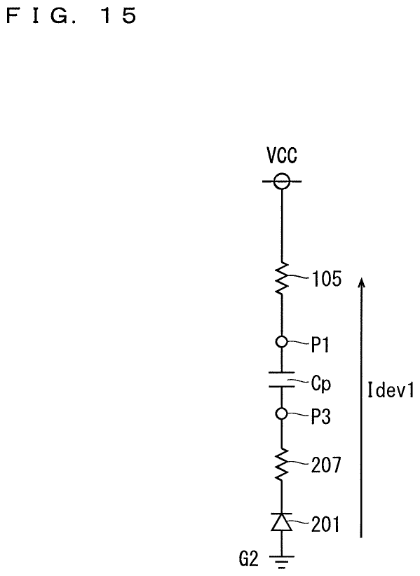

FIGS. 14 and 15 are circuit diagrams illustrating elements through which displacement currents Idev1 and Idev2 flow when the potential G2 rises with respect to the potential G1 under the influence of the voltage variation Vdif. FIG. 14 illustrates a path through which the displacement current Idev2 flows via the transistor 103. FIG. 15 illustrates a path through which the displacement current Idev1 flows via the resistor 105.

In the path illustrated in FIG. 14, the displacement current Idev2 flows from a diode 203 and a resistor 208 of a clamp circuit 206 to the transistor 103 via a parasitic capacitance Cp parasitic on a transformer 10 between the second end P2 and a fourth end P4.

In the path illustrated in FIG. 15, the displacement current Idev1 flows from a diode 201 and a resistor 207 of a clamp circuit 205 to the resistor 105 via the parasitic capacitance Cp parasitic on the transformer 10 between the first end P1 and a third end P3.

Here, the displacement currents Idev1 and Idev2 occur in a transition period in which a time derivative dv/dt occurs. The displacement currents Idev1 and Idev2 do not flow between the first end P1 and the second end P2 to which first coil 11 is connected or between the third end P3 and the fourth end P4 to which the second coil 12 is connected. This is because the frequencies of the displacement currents Idev1 and Idev2 generated in the transition period are high, and the impedances of both the first coil 11 and the second coil 12 are high.

When the first circuit 100 illustrated in FIG. 1 is adopted, a potential difference is generated between the first end P1 and the second end P2 due to the on-resistance of the transistor 103 and the displacement current Idev2. Such a potential difference influences a decrease in the amplitude of each pulse of the signal J1 generated by the pulse generation circuit 101, and thus, the amplitudes of the signals VRO1 and VRO2 input to the detection circuit 240, and hence, there is a possibility that correct detection cannot be performed and malfunction occurs. The resistor 105 adopted in the first modification contributes to the suppression of the potential difference and thus contributes to the suppression of the malfunction.

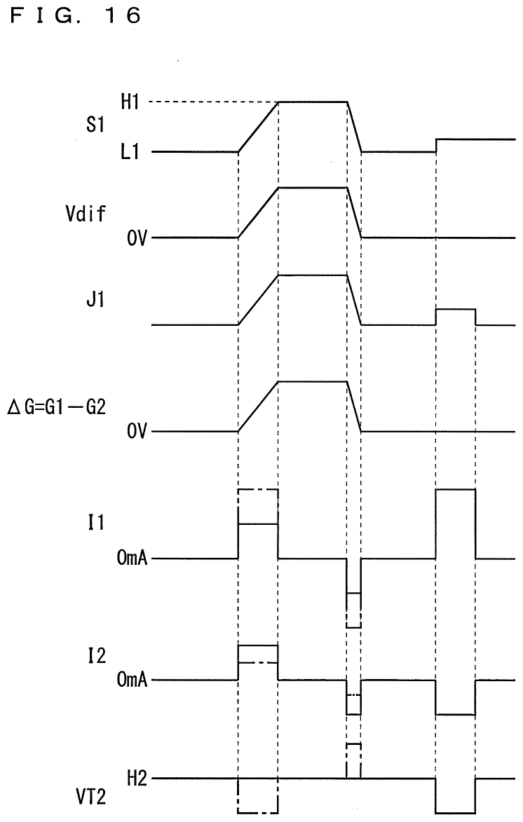

FIG. 16 is a waveform diagram illustrating temporal changes in various signals in the first modification of the first circuit 100. Specifically, FIG. 16 illustrates the waveforms of the first signal S1, the signal J1, a potential difference AG, currents I1 and I2, and a transmission signal VT2 are illustrated.

The current I1 flows through the first end P1, and the current I2 flows through the second end P2. Referring to FIG. 1, the direction from the first circuit 100 to the first coil 11 is positive for each of the currents I1 and I2. A value H1 of the first signal S1 corresponds to logical value “H” of the first signal S1. A value L1 of the first signal S1 corresponds to logical value “L” of the first signal S1. A value H2, with reference to the potential G1, of the transmission signal VT2 corresponds to logical value “H” of the transmission signal VT2. The potential difference AG is the voltage (G1-G2) of the potential G1 with reference to the potential G2.

The waveforms indicated by the chain lines indicate a case where the first circuit 100 without the resistor 105 illustrated in FIG. 1 is adopted, and the waveforms indicated by the solid lines indicate a case where the first modification is adopted.

FIG. 16 also illustrates the waveform of the voltage variation Vdif. FIG. 16 exemplifies the occurrence of two events, namely, an increase and a decrease in the time derivative dv/dt in the first coil 11 with respect to the second coil 12.

As indicated by the chain lines, in the absence of the resistor 105, the waveforms of the currents I1 and I2 greatly differ from each other. This is because: the first end P1 is connected to the source of the transistor 103, and the second end P2 is connected to the drain of the transistor 103; the ON resistance of the transistor 103 exists between the first end P1 and the second end P2; and the resistance value from the first end P1 to the power supply which applies the potential VCC is different from the resistance value from the second end P2 to the power supply.

Owing to the difference between the currents I1 and I2, the potential of the transmission signal VT2 temporarily decreases. When a period in which the voltage variation Vdif rises due to the fall of the time derivative dv/dt overlaps a period in which pulses are generated in the logical value of the signal J1, the pulses may be canceled out and disappear to cause a malfunction that the first circuit 100 cannot correctly transmit the transmission signal VT2.

When the resistor 105 is provided, the impedance of the path (see FIG. 15) through which the displacement current Idev1 flows and the impedance of the path (see FIG. 14) through which the displacement current Idev2 flows can be brought close to each other by adjusting the resistance value. As a result, the waveforms of the currents I1 and I2 are approximated each other, the potential of the transmission signal VT2 is less likely to fluctuate, and pulses are less likely to disappear. In this way, the resistor 105 contributes to the prevention of the malfunction of the first circuit 100, and thus, contributes to the output of the appropriate second signal S2.

The first modification can be applied to any of the first circuits 100a, 100b, 100x, and 100y. By such application, obtained are second signals S2a, S2b, S2x, and S2y appropriately reflecting first signals S1a, S1b, S1x, and S1y, specifically, reflecting the pulse trains generated in the signals J1a, J1b, J1x, and J1y. The application of the first modification contributes to the output potential OUT output from the power conversion apparatus 2000 appropriately reflecting the input signal IN.

### <5. Second Modification of First Circuit>

A fifth preferred embodiment of the present disclosure relates to a second modification of each of the first circuits 100, 100a, 100b, 100x, and 100y. The second modification of the first circuit 100 will be described first below.

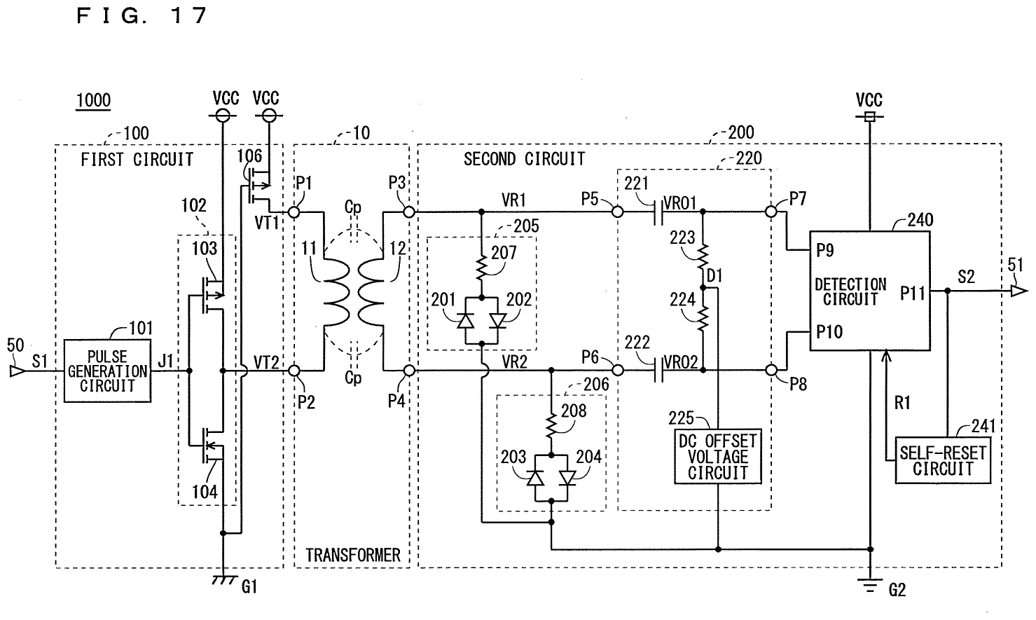

FIG. 17 is a circuit diagram illustrating the configuration of the signal transmission circuit 1000 to which the second modification of the first circuit 100 is applied. The second modification of the first circuit 100 has a configuration in which the resistor 105 of the first modification of the first circuit 100 is replaced with a transistor 106 in the ON state.

Specifically, in the second modification, the first circuit 100 further includes the P-channel transistor 106. The transistor 106 includes a drain connected to the first end P1 and a source to which a fixed potential VCC is applied. In the first circuit 100 illustrated in FIG. 1, the potential VT1 is output from the source of the transistor 103 to the first end P1. However, in the second modification, a potential VT1 is output from the drain of the transistor 106 to a first end P1.

For example, a potential G1 is applied to the gate of the transistor 106. The potential G1 is lower than the potential VCC applied to the source, and the ON state of the transistor 106 is maintained.

As the transistor 106, a P-channel transistor having an on-resistance value having a small difference from the on-resistance value of the transistor 103 is adopted.

Owing to the similarity that both the transistors 106 and 103 are P-channel transistors, the temperature characteristics of the on-resistance values of both the transistors are similar. Such similarity in temperature characteristics brings about an advantage that the action of preventing the malfunction of the first circuit 100 is less likely to depend on the temperature environment in which the first circuit 100 is used and is easily obtained in a wide temperature range as compared with the fourth exemplary preferred embodiment.

Even if the on-resistance values of the transistors 103 and 106 differ from each other, the effect of reducing the difference between the above two types of displacement currents can be obtained even if there is a difference in effect due to the degree of the difference.

An IGBT may be adopted as the transistor 103. For example, when an IGBT is adopted as the transistor 103, an IGBT is also adopted as the transistor 106. It can be said that the collector and the emitter of the IGBT are a first electrode and a second electrode that are electrically connected to each other by a signal applied to the gate. It can be said that the gate is a third electrode that controls conduction between the first electrode and the second electrode.

In the first circuit 100, the first end P1 and the source of the transistor 104 can be connected via an N-channel transistor in the ON state. As the N-channel transistor in this case, a transistor having an on-resistance value having a small difference from the on-resistance value of the transistor 104 is adopted.

Even if the on-resistance value of the N-channel transistor is different from the on-resistance value of the transistor 103, the effect of reducing the difference between the above two types of displacement currents can be obtained even if there is a difference in effect due to the degree of the difference.

An IGBT may be adopted as the transistor 104. For example, when an IGBT is adopted for the transistor 104, an IGBT in the ON state is adopted instead of the above N-channel transistor.

The second modification can be applied to any of the first circuits 100a, 100b, 100x, and 100y. By such application, obtained are second signals S2a, S2b, S2x, and S2y appropriately reflecting first signals S1a, S1b, S1x, and S1y, specifically, reflecting the pulse trains generated in the signals J1a, J1b, J1x, and J1y. The application of the second modification contributes to the output potential OUT output from the power conversion apparatus 2000 appropriately reflecting the input signal IN.

### <6. Modification of Limitation on Displacement Current>

Referring to FIGS. 1 and 11, for example, the higher the resistance value of the resistor 207 in the clamp circuit 205, the larger the voltage drop in the resistor 207, and the higher the voltage supported by the diodes 201 and 202, thus making it easy to suppress the influence of the voltage variation Vdif.

The magnitude of a current limiting resistor can also be set from the following viewpoints. For example, when the rectification characteristics of the diodes 201 and 202 are improved in the clamp circuit 205, a displacement current can be limited even if the resistance value of the resistor 207 is lowered, and typically, the resistor 207 may be omitted.

However, when the resistor 207 is omitted, even if a displacement current is suppressed, the reception signals VR1 and VR2 are also suppressed, which is undesirable from the viewpoint of transmitting signals. On the other hand, it is not desirable to lower the rectification characteristics of the diodes 201 and 202 and increase the resistance value of the resistor 207 from the viewpoint of loosening the restriction on a displacement current. It is desirable to set the resistor 207 in consideration of such a trade-off. The same applies to the resistors 208, 207a, 208a, 207b, 208b, 207x, 208x, 207y, and 208y.

For example, a displacement current can be limited as follows in consideration of the appropriate voltage range of the detection circuit 240, the DC voltage D1, and the assumed time derivative dv/dt.

The upper limit of the appropriate voltage range is substantially lowered by the clamp circuit 205. The lower limit of the appropriate voltage range is substantially increased by the clamp circuit 206. Both the substantial decrease and the increase will be described on the assumption that their absolute values are 1 V.

For example, even when the appropriate voltage range is 0 V to 5 V, the substantial upper limit is lowered to 4 V by the clamp circuit 205, and the substantial upper limit is raised to 1 V by the clamp circuit 206. When the appropriate voltage range is 0 V to 5 V, the median value 2.5 V is adopted as the DC voltage D1. Even if the appropriate voltage range has a substantial upper limit of 4 V and a substantial lower limit of 0 V due to the clamp circuits 205 and 206, the DC voltage D1 may be 2.5 V. This is because the median value between the upper limit and the lower limit is also 2.5 V.

When a displacement current is limited by the clamp circuit 205 and the displacement current is not limited by the clamp circuit 206, the appropriate voltage range is substantially narrowed from the range of 0 V to 5 V to the range of 0 V to 4 V. In this case, the DC voltage D1 desirably has a median value of 2 V in the range of 0 V to 4 V.

Alternatively, when the appropriate voltage range is 0 V to 5 V, but the operation in a region near the boundary is unstable, the region where the operation is unstable may be substantially eliminated using the clamp circuits 205 and 206. For example, when the operation of the detection circuit 240 at 0 V to 0.5 V is unstable, the substantially lower limit of the appropriate voltage range is set to 0.5 V by the clamp circuit 206. For example, when the operation of the detection circuit 240 at 4.5 V to 5 V is unstable, the substantially upper limit of the appropriate voltage range is set to 4.5 V by the clamp circuit 205. Setting the clamp circuits 205 and 206 in this manner to substantially narrow the appropriate voltage range contributes to avoiding an unstable operation of the detection circuit 240.

It is assumed that the appropriate voltage range is 0 V to 5 V, the median value 2.5 V of the DC voltage D1 is adopted, and the substantially appropriate voltage range is narrowed to the range of 2 V to 3 V by the clamp circuits 205 and 206. In such a case, assuming that a variation of the reception signal VR1 increases due to the voltage variation Vdif (see FIG. 2), and for example, a variation of 1 V occurs, the signal VRO1 rises to 3.5 (=2.5+1) V with respect to the potential G2. At this time, the potential of the signal VRO1 exceeds 3 V, which is the upper limit of the appropriate voltage range of the detection circuit 240, and a malfunction may occur in the detection circuit 240.

When the occurrence of the voltage variation Vdif that causes such variation in the reception signal VR1 is assumed, it is desirable to design the clamp circuit 205 such that the upper limit of the substantial appropriate voltage range is higher than 3.5 V, for example, 4 V. If the clamp circuit 205 is designed such that the upper limit of the substantial appropriate voltage range is 4 V and the DC voltage D1 is maintained at 2.5 V, it is desirable to design the clamp circuit 206 such that the lower limit of the substantial appropriate voltage range is 1 V.

The clamp circuits 205a, 206a, 205b, 206b, 205x, 206x, 205y, and 206y can be similarly designed.

<7. Modification of Lower Arm Circuit 2000b>

The output potential OUT serves as a reference for potentials in the signal transmission circuits 1000a and 1000b of the upper arm circuit 2000a. Therefore, similarly to the potential G2 serving as a reference for the potential in the signal transmission circuit 1000, it is desired to reduce the influence of the voltage variation Vdif caused by a variation in the output potential OUT. On the other hand, the potential G3 serving as a reference for potentials in the signal transmission circuits 1000x and 1000y of the lower arm circuit 2000b does not necessarily cause the voltage variation Vdif. From this viewpoint, the signal transmission circuits 1000x and 1000y do not necessarily have the same configuration as the signal transmission circuit 1000.

Specifically, for example, the self-reset circuits 241x and 241y may be omitted in the signal transmission circuits 1000x and 1000y.

Note that the respective preferred embodiments can be freely combined and can be modified and omitted as needed.

Hereinafter, various aspects of the present disclosure will be collectively described as appendixes.

### Appendix 1

A signal transmission circuit comprising:
a first circuit, to which a first signal is input, configured to generate a transmission signal according to a change in a logical value of the first signal, and uses a first potential as a reference for an operation;
a transformer including a first coil to which the transmission signal is input from the first circuit and a second coil inductively coupled to the first coil and configured to output a pair of reception signals; and
a second circuit, to which the pair of reception signals are input from the second coil, configure to generate a second signal by performing comparison with hysteresis with respect to a potential difference between the pair of reception signals, and use a second potential as a reference for an operation,
wherein the second circuit includes a detection circuit configured to perform the comparison and output a result of detecting whether the potential difference exceeds a predetermined range as the second signal and a reset circuit configured to reset an operation of the detection circuit when a logical value of the second signal is maintained in a preset period.

### Appendix 2

The signal transmission circuit according to appendix 1, wherein
the second circuit further includes an offset circuit configured to generate a pair of third signals obtained by applying a DC voltage with reference to the second potential as an offset voltage to the pair of reception signals, and
the detection circuit generates the second signal by performing the comparison with respect to a potential difference between the pair of third signals generated by the offset circuit.

### Appendix 3

The signal transmission circuit according to appendix 2, wherein the offset circuit includes
a first input terminal to which one of the pair of reception signals is input,
a second input terminal to which the other of the pair of reception signals is input,
a first output terminal to which one of the pair of third signals is input,
a second output terminal to which the other of the pair of third signals is input,
a first resistor having one end connected to the first output terminal and the other end to which the DC voltage is applied,
a second resistor having one end connected to the second output terminal and the other end to which the DC voltage is applied,
a first capacitor connected between the first input terminal and the first output terminal, and
a second capacitor connected between the second input terminal and the second output terminal.

### Appendix 4

The signal transmission circuit according to appendix 3, wherein
the second circuit further includes a first clamp circuit and a second clamp circuit connected in series between the first input terminal and the second input terminal,
the first clamp circuit includes
   a first diode,
   a second diode connected in parallel with the first diode and having a forward direction opposite to a forward direction of the first diode, and
   a first current limiting resistor connected in series to each of the first diode and the second diode, and
the second clamp circuit includes
   a third diode,
   a fourth diode connected in parallel with the third diode and having a forward direction opposite to a forward direction of the third diode, and
   a second current limiting resistor connected in series to each of the third diode and the fourth diode.

### Appendix 5

The signal transmission circuit according to any one of appendixes 1 to 4, wherein
the first circuit includes
   a pulse generation circuit configured to generate a fourth signal in which a first pulse train having a plurality of pulses in a part of a period in which the first signal takes a first logical value and a second pulse train having a plurality of pulses following the first pulse train in the part occur, and
   an output circuit configured to generate the transmission signal according to a change in a logical value of the fourth signal, and
one period of a pulse in the second pulse train is longer than one period of a pulse in the first pulse train.

### Appendix 6

The signal transmission circuit according to appendix 5, wherein
the output circuit includes a transistor including a first electrode to which a fixed potential is applied, a second electrode configured to output the transmission signal, and a third electrode to which the fourth signal is applied and which controls conduction between the first electrode and the second electrode, and
the first circuit further includes a third resistor having one end connected to one end of the first coil and the other end to which the fixed potential is applied.

### Appendix 7

The signal transmission circuit according to appendix 5, wherein
the output circuit includes a first transistor including a first electrode to which a fixed potential is applied, a second electrode configured to output the transmission signal, and a third electrode to which the fourth signal is applied and which controls conduction between the first electrode and the second electrode, and
the first circuit further includes a second transistor in an ON state which has a first electrode connected to one end of the first coil and a second electrode to which the fixed potential is applied.

### Appendix 8

A power conversion apparatus comprising:
an output line;
a first switching element having one end to which a fixed potential is applied and the other end connected to the output line;
a second switching element having one end connected to the output line and the other end to which a third potential is applied and configured to be turned on exclusively with respect to the first switching element;
a first signal transmission circuit as which the signal transmission circuit according to any one of appendixes 1 to 5 is adopted;
a second signal transmission circuit as which the signal transmission circuit according to any one of appendixes 1 to 5 is adopted; and
a first latch circuit configured to output a signal for controlling whether to permit conduction of the first switching element, be set by the second signal output from the first signal transmission circuit, and be reset by the second signal output from the second signal transmission circuit,
wherein both the second potential in the first signal transmission circuit and the second potential in the second signal transmission circuit are a potential of the output line.

### Appendix 9

The power conversion apparatus according to appendix 8, further comprising:
a third signal transmission circuit as which the signal transmission circuit according to any one of appendixes 1 to 5 is adopted;
a fourth signal transmission circuit as which the signal transmission circuit according to any one of appendixes 1 to 5 is adopted; and
a second latch circuit configured to output a signal for controlling whether to permit conduction of the second switching element, be set by the second signal output from the third signal transmission circuit, and be reset by the second signal output from the fourth signal transmission circuit,
wherein both the second potential in the third signal transmission circuit and the second potential in the fourth signal transmission circuit are the third potential.

While the disclosure has been shown and described in detail, the foregoing description is in all aspects illustrative and not restrictive. It is therefore understood that numerous modifications and variations can be devised.

What is claimed is:

1. A signal transmission circuit comprising:
a first circuit, to which a first signal is input, configured to generate a transmission signal according to a change in a logical value of the first signal, and use a first potential as a reference for an operation;
a transformer including a first coil to which the transmission signal is input from the first circuit and a second coil inductively coupled to the first coil and configured to output a pair of reception signals; and
a second circuit, to which the pair of reception signals are input from the second coil, configured to generate a second signal by performing comparison with hysteresis with respect to a potential difference between the pair of reception signals, and use a second potential as a reference for an operation,
wherein
the second circuit includes a detection circuit configured to perform the comparison and output a result of detecting whether the potential difference exceeds a predetermined range as the second signal, and
a reset circuit configured to reset an operation of the detection circuit when a logical value of the second signal is maintained in a preset period.

2. The signal transmission circuit according to claim 1, wherein
the second circuit further includes an offset circuit configured to generate a pair of third signals obtained by applying a DC voltage with reference to the second potential as an offset voltage to the pair of reception signals, and
the detection circuit generates the second signal by performing the comparison with respect to a potential difference between the pair of third signals generated by the offset circuit.

3. The signal transmission circuit according to claim 2, wherein
the offset circuit includes
a first input terminal to which one of the pair of reception signals is input,
a second input terminal to which the other of the pair of reception signals is input,
a first output terminal to which one of the pair of third signals is input,
a second output terminal to which the other of the pair of third signals is input,
a first resistor having one end connected to the first output terminal and the other end to which the DC voltage is applied,
a second resistor having one end connected to the second output terminal and the other end to which the DC voltage is applied,
a first capacitor connected between the first input terminal and the first output terminal, and
a second capacitor connected between the second input terminal and the second output terminal.

4. The signal transmission circuit according to claim 3, wherein
the second circuit further includes a first clamp circuit and a second clamp circuit connected in series between the first input terminal and the second input terminal,
the first clamp circuit includes
a first diode,
a second diode connected in parallel with the first diode and having a forward direction opposite to a forward direction of the first diode, and
a first current limiting resistor connected in series to each of the first diode and the second diode, and
the second clamp circuit includes
a third diode,
a fourth diode connected in parallel with the third diode and having a forward direction opposite to a forward direction of the third diode, and
a second current limiting resistor connected in series to each of the third diode and the fourth diode.

5. The signal transmission circuit according to claim 1, wherein
the first circuit includes
a pulse generation circuit configured to generate a fourth signal in which a first pulse train having a plurality of pulses in a part of a period in which the first signal takes a first logical value and a second pulse train having a plurality of pulses following the first pulse train in the part occur, and
an output circuit configured to generate the transmission signal according to a change in a logical value of the fourth signal, and
one period of a pulse in the second pulse train is longer than one period of a pulse in the first pulse train.

6. The signal transmission circuit of claim 5, wherein
the output circuit includes a transistor including a first electrode to which a fixed potential is applied, a second electrode configured to output the transmission signal, and a third electrode to which the fourth signal is applied and which controls conduction between the first electrode and the second electrode, and
the first circuit includes a third resistor having one end connected to one end of the first coil and the other end to which the fixed potential is applied.

7. The signal transmission circuit according to claim 5, wherein
the output circuit includes a first transistor including a first electrode to which a fixed potential is applied, a second electrode configured to output the transmission signal, and a third electrode to which the fourth signal is applied and which controls conduction between the first electrode and the second electrode, and
the first circuit includes a second transistor in an ON state which has a first electrode connected to one end of the first coil and a second electrode to which the fixed potential is applied.

8. The signal transmission circuit according to claim 2, wherein
the first circuit includes
a pulse generation circuit configured to generate a fourth signal in which a first pulse train having a plurality of pulses in a part of a period in which the first signal takes a first logical value and a second pulse train having a plurality of pulses following the first pulse train in the part occur, and
an output circuit configured to generate the transmission signal according to a change in a logical value of the fourth signal, and
one period of a pulse in the second pulse train is longer than one period of a pulse in the first pulse train.

9. The signal transmission circuit of claim 8, wherein
the output circuit includes a transistor including a first electrode to which a fixed potential is applied, a second electrode configured to output the transmission signal, and a third electrode to which the fourth signal is applied and which controls conduction between the first electrode and the second electrode, and
the first circuit includes a third resistor having one end connected to one end of the first coil and the other end to which the fixed potential is applied.

10. The signal transmission circuit according to claim 8, wherein
the output circuit includes a first transistor including a first electrode to which a fixed potential is applied, a second electrode configured to output the transmission signal, and a third electrode to which the fourth signal is applied and which controls conduction between the first electrode and the second electrode, and
the first circuit includes a second transistor in an ON state which has a first electrode connected to one end of the first coil and a second electrode to which the fixed potential is applied.

11. The signal transmission circuit according to claim 3, wherein
the first circuit includes
a pulse generation circuit configured to generate a fourth signal in which a first pulse train having a plurality of pulses in a part of a period in which the first signal takes a first logical value and a second pulse train having a plurality of pulses following the first pulse train in the part occur, and
an output circuit configured to generate the transmission signal according to a change in a logical value of the fourth signal, and
one period of a pulse in the second pulse train is longer than one period of a pulse in the first pulse train.

12. The signal transmission circuit of claim 11 wherein
the output circuit includes a transistor including a first electrode to which a fixed potential is applied, a second electrode configured to output the transmission signal, and a third electrode to which the fourth signal is applied and which controls conduction between the first electrode and the second electrode, and
the first circuit includes a third resistor having one end connected to one end of the first coil and the other end to which the fixed potential is applied.

13. The signal transmission circuit according to claim 11, wherein
the output circuit includes a first transistor including a first electrode to which a fixed potential is applied, a second electrode configured to output the transmission signal, and a third electrode to which the fourth signal is applied and which controls conduction between the first electrode and the second electrode, and
the first circuit includes a second transistor in an ON state which has a first electrode connected to one end of the first coil and a second electrode to which the fixed potential is applied.

14. The signal transmission circuit according to claim 4, wherein
the first circuit includes
a pulse generation circuit configured to generate a fourth signal in which a first pulse train having a plurality of pulses in a part of a period in which the first signal takes a first logical value and a second pulse train having a plurality of pulses following the first pulse train in the part occur, and
an output circuit configured to generate the transmission signal according to a change in a logical value of the fourth signal, and
one period of a pulse in the second pulse train is longer than one period of a pulse in the first pulse train.

15. The signal transmission circuit of claim 14, wherein
the output circuit includes a transistor including a first electrode to which a fixed potential is applied, a second electrode configured to output the transmission signal, and a third electrode to which the fourth signal is applied and which controls conduction between the first electrode and the second electrode, and
the first circuit includes a third resistor having one end connected to one end of the first coil and the other end to which the fixed potential is applied.

16. The signal transmission circuit according to claim 14, wherein
the output circuit includes a first transistor including a first electrode to which a fixed potential is applied, a second electrode configured to output the transmission signal, and a third electrode to which the fourth signal is applied and which controls conduction between the first electrode and the second electrode, and
the first circuit includes a second transistor in an ON state which has a first electrode connected to one end of the first coil and a second electrode to which the fixed potential is applied.

17. A power conversion apparatus comprising:
an output line;
a first switching element having one end to which a fixed potential is applied and the other end connected to the output line;
a second switching element having one end connected to the output line and the other end to which a third potential is applied and configured to be turned on exclusively with respect to the first switching element;
a first signal transmission circuit and a second signal transmission circuit as each of which the signal transmission circuit according to claim 1 is adopted; and
a first latch circuit configured to output a signal for controlling whether to permit conduction of the first switching element, be set by the second signal output from the first signal transmission circuit, and be reset by the second signal output from the second signal transmission circuit,
wherein both the second potential in the first signal transmission circuit and the second potential in the second signal transmission circuit are a potential of the output line.

18. A power conversion apparatus comprising:
an output line;
a first switching element having one end to which a fixed potential is applied and the other end connected to the output line;
a second switching element having one end connected to the output line and the other end to which a third potential is applied and configured to be turned on exclusively with respect to the first switching element;
a first signal transmission circuit, a second signal transmission circuit, a third signal transmission circuit, and a fourth signal transmission circuit, as each of which the signal transmission circuit according to claim 1 is adopted;
a first latch circuit configured to output a signal for controlling whether to permit conduction of the first switching element, be set by the second signal output from the first signal transmission circuit, and be reset by the second signal output from the second signal transmission circuit; and
a second latch circuit configured to output a signal for controlling whether to permit conduction of the second switching element, be set by the second signal output from the third signal transmission circuit, and be reset by the second signal output from the fourth signal transmission circuit, wherein
both the second potential in the first signal transmission circuit and the second potential in the second signal transmission circuit are a potential of the output line, and
both the second potential in the third signal transmission circuit and the second potential in the fourth signal transmission circuit are the third potential.
